(19) United States
(12) Patent Application Publication
(10) Pub. No.: US 2026/0215007 A1
(43) Pub. Date: Jul. 23, 2026

(54) PIXEL OF IMAGE SENSOR AND METHOD OF MANUFACTURING THE SAME

(71) Applicant: Samsung Electronics Co., Ltd., Suwon-si (KR)

(72) Inventors: Hyeongdong Jo, Suwon-si (KR); Haewon Lee, Suwon-si (KR)

(21) Appl. No.: 19/404,146

(22) Filed: Dec. 1, 2025

(30) Foreign Application Priority Data
Jan. 22, 2025 (KR) 10-2025-0009848

(51) Int. Cl. H10F 39/00; H10F 39/18

(52) U.S. Cl. CPC H10F 39/014; H10F 39/182; H10F 39/802; H10F 39/80373; H10F 39/811

(57) ABSTRACT

A pixel of an image sensor includes a photodiode, a floating diffusion region, a first gate and a second transistor. The first gate is a transfer gate, and the transfer gate is a part of a first transistor. The photodiode is disposed in a lower portion of a semiconductor substrate. The floating diffusion region is disposed in an upper portion of the semiconductor substrate. The first gate includes a first lower gate disposed on the semiconductor substrate and an first upper gate disposed on the first lower gate. The second transistor includes a first source/drain region, a second source/drain region and a second gate. The first source/drain region and the second source/drain region are disposed in the upper portion of the semiconductor substrate. The second gate is disposed on the semiconductor substrate between the first source/drain region and the second source/drain region. The second gate includes a second lower gate and an upper second transistor disposed on the second lower gate.

### CROSS-REFERENCE TO RELATED APPLICATION

This U.S. non-provisional application claims priority under 35 USC § 119 to Korean Patent Application No. 10-2025-0009848, filed on Jan. 22, 2025, in the Korean Intellectual Property Office (KIPO), the disclosure of which is incorporated by reference herein in its entirety.

### BACKGROUND

### 1. Technical Field

Example embodiments relate generally to semiconductor integrated circuits, and more particularly to a pixel of an image sensor and a method of manufacturing an image sensor.

### 2. Discussion of the Related Art

Complementary metal oxide semiconductor (CMOS) image sensors are solid-state sensing devices that use complementary metal oxide semiconductors. CMOS image sensors have lower manufacturing costs and/or lower power consumption compared with charge-coupled device (CCD) image sensors. Thus, CMOS image sensors are used for various electronic appliances including portable devices such as, for example, smartphones and digital cameras.

A pixel array included in a CMOS image sensor may include a photoelectric conversion element such as a photodiode in each pixel. The photoelectric conversion element generates an electrical signal that varies based on the quantity of incident light. The CMOS image sensor processes electrical signals to synthesize an image. With the recent proliferation of higher-resolution images, pixels included in the CMOS image sensor are becoming much smaller. When the pixels get smaller, incident light may not be properly sensed and/or noise may occur due to interference between more highly integrated elements.

### SUMMARY

Some example embodiments may provide a pixel of an image sensor having enhanced electrical characteristics, and a method of manufacturing an image sensor.

According to example embodiments, a pixel of an image sensor includes: a photodiode disposed in a lower portion of a semiconductor substrate; a floating diffusion region disposed in an upper portion of the semiconductor substrate; a first gate including a first lower gate disposed on the semiconductor substrate and a first upper gate disposed on the first lower gate; and a second transistor including a first source/drain region, a second source/drain region and a second gate. The first gate is a transfer gate, and the transfer gate is a part of a first transistor. The first source/drain region and the second source/drain region are disposed in the upper portion of the semiconductor substrate. The second transistor is disposed on the semiconductor substrate between the first source/drain region and the second source/drain region, and the second gate includes a second lower gate and a second upper gate disposed on the second lower gate.

According to example embodiments, a method of manufacturing an image sensor including a pixel, includes, forming a gate insulating layer on a semiconductor substrate, forming a first poly layer on the gate insulating layer by performing a first deposition process, forming a first lower gate and a second lower gate simultaneously by patterning the first poly layer, forming a second poly layer on the first lower gate and the second lower gate by performing a second deposition process, forming a first upper gate and a second upper gate on the first lower gate and the second lower gate simultaneously by patterning the second poly layer. The first lower gate and the first upper gate constitute a transfer gate, and the transfer gate is a part of a transfer transistor.

According to example embodiments, an image sensor includes a pixel array including a plurality of pixels configured to perform a sensing operation by collecting photo-charges generated by incident light, a row driver configured to drive the pixel array row by row, and a controller configured to control the pixel array and the row driver. A pixel of the plurality of pixels includes a photodiode disposed in a lower portion of a semiconductor substrate, a floating diffusion region disposed in an upper portion of the semiconductor substrate, a first gate including a first lower gate disposed on the semiconductor substrate and a first upper gate disposed on the first lower gate, and a second transistor including a first source-drain region, a second source-drain region and a second gate. The first gate is a transfer gate, and the transfer gate is a part of a first transistor. The first source-drain region and the second source-drain region are disposed in the upper portion of the semiconductor substrate. The second gate is disposed on the semiconductor substrate between the first source-drain region and the second source-drain region. The second gate includes a second lower gate and a second upper gate disposed on the second lower gate.
According to example embodiments, an image sensor includes a pixel array including first and second pixels which are adjacent to each other, and a pixel isolator electrically isolating the first pixel from the second pixel. Each of the first and second pixels includes: a photodiode disposed in a lower portion of a semiconductor substrate, and a floating diffusion region disposed in an upper portion of the semiconductor substrate. The first pixel further includes a first transistor including a first gate, and the second pixel further includes a second transistor including a second gate. Each of the first gate and a second gate includes a first portion and a second portion. In a plan view, the first portion may be more spaced apart from the pixel isolator than the second portion.

The pixel of the image sensor according to example embodiments may reduce coupling capacitance between gates and other components and improve electrical characteristics of the pixel and image sensor, by adopting the dual-gate structure including the lower gate and the upper gate having the smaller horizontal size than the lower gate.

Furthermore, the pixels of the image sensor according to example embodiments may efficiently improve the electrical characteristics of the pixel and image sensor without excessive changes to the existing layout design by changing only the size and position of the upper gate while keeping the layout of the lower gate unchanged.

### BRIEF DESCRIPTION OF THE DRAWINGS

Example embodiments of the present disclosure will be more clearly understood from the following detailed description taken in conjunction with the accompanying drawings.

FIG. 1 is a cross-sectional diagram illustrating a pixel of an image sensor according to example embodiments.

FIG. 2 is a diagram illustrating a gate included in a pixel of an image sensor according to example embodiments.

FIGS. 3A through 3L are cross-sectional diagrams illustrating a method of manufacturing an image sensor according to example embodiments.

FIGS. 4A and 4B are diagrams illustrating example embodiments of arrangement of upper gates in pixels of an image sensor according to example embodiments.

FIG. 5A is a block diagram illustrating an image sensor according to example embodiments.

FIG. 5B is a circuit diagram illustrating an example of a unit circuit included in an image sensor according to example embodiments.

FIG. 5C is a timing diagram illustrating an example operation of an image sensor according to example embodiments.

FIG. 6 is a diagram illustrating an example embodiment of a configuration of pixels and a readout circuit according to example embodiments.

FIG. 7 is a diagram illustrating an example embodiment of a layout of an image sensor according to example embodiments.

FIG. 8 is a cross-sectional diagram illustrating a vertical structure along a line A1-A1′ in FIG. 7.

FIG. 9 is a diagram illustrating an enlarged view of a portion of FIG. 8.

FIG. 10 is a diagram drawn along a horizontal cross-section at the first vertical level of FIG. 8.

FIG. 11 is a diagram drawn along a horizontal cross-section at the second vertical level of FIG. 8.

FIGS. 12A and 12B are diagrams illustrating example embodiments of a pixel isolator included in an image sensor according to example embodiments.

FIGS. 13 through 17, 18A, 18B, 19 and 20 are diagrams illustrating a method of manufacturing an image sensor according to example embodiments.

FIG. 21 is a diagram illustrating a perspective view of an image sensor according to example embodiments.

FIG. 22 is a block diagram illustrating an electronic device according to example embodiments.

FIG. 23 is a block diagram illustrating a camera module included in the electronic device of FIG. 22.

### DETAILED DESCRIPTION OF THE EXAMPLE EMBODIMENTS

Various example embodiments will be described more fully hereinafter with reference to the accompanying drawings, in which some example embodiments are shown. In the drawings, like numerals refer to like elements throughout. The repeated descriptions may be omitted.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Terms such as “intrinsic,” “undoped,” “same,” “equal,” “constant,” “flat,” etc. as used herein, are intended to encompass meanings that include typical variations resulting from conventional manufacturing processes and/or accommodate tolerances acceptable in the manufacturing process of the semiconductor device, unless the context or other statements indicate otherwise. For example, ‘same’ and ‘equal’ may encompass identicality or near identicality. The term “substantially” may be used herein to emphasize this meaning. For example, ‘same’ and ‘equal’ may encompass identicality or near identicality. The term “substantially” may be used herein to emphasize this meaning. In another example, when a semiconductor region is an intrinsic semiconductor region, the net doping concentration (the difference between concentrations of donor and acceptor) may not be exactly zero but sufficiently low enough (or close to zero), as long as the effect of the net doping concentration is negligible.

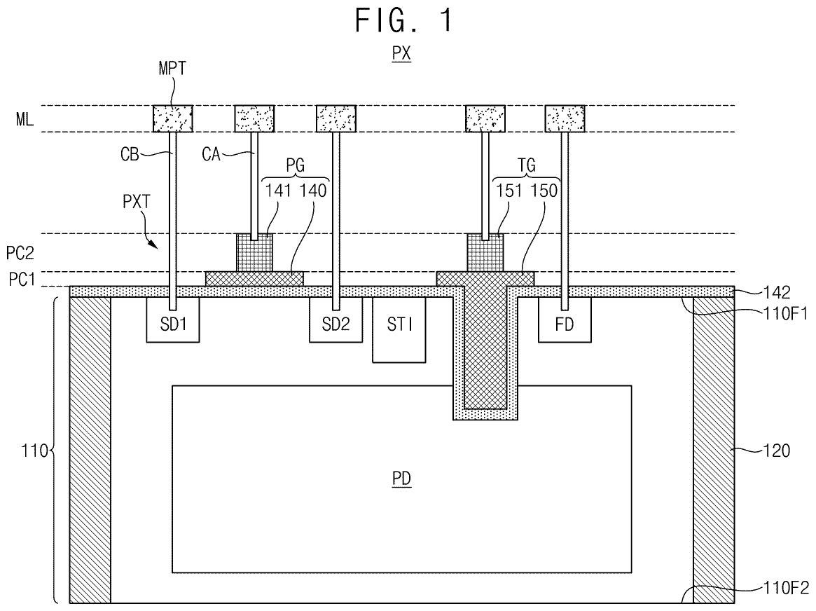

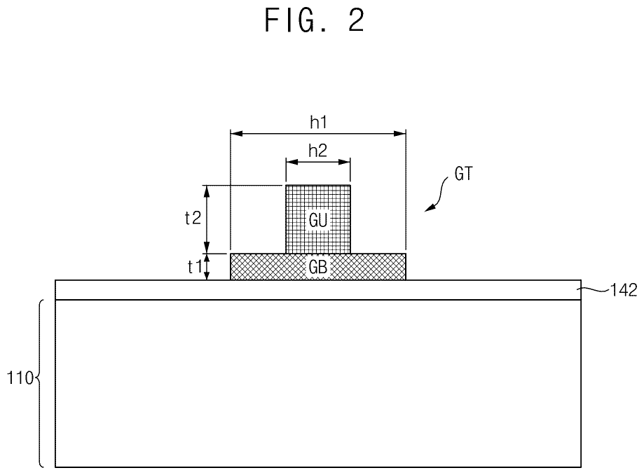

FIG. 1 is a cross-sectional diagram illustrating a pixel of an image sensor according to example embodiments, and FIG. 2 is a diagram illustrating a gate included in a pixel of an image sensor according to example embodiments.

FIG. 1 illustrates a single pixel surrounded by a pixel isolator 120 defining a plurality of pixels. The pixel isolator 120 may be formed within a pixel trench that penetrates the semiconductor substrate 110 from an upper surface or first surface 110F1 of a semiconductor substrate 110 to a lower surface or second surface 110F2 of the semiconductor substrate 110.

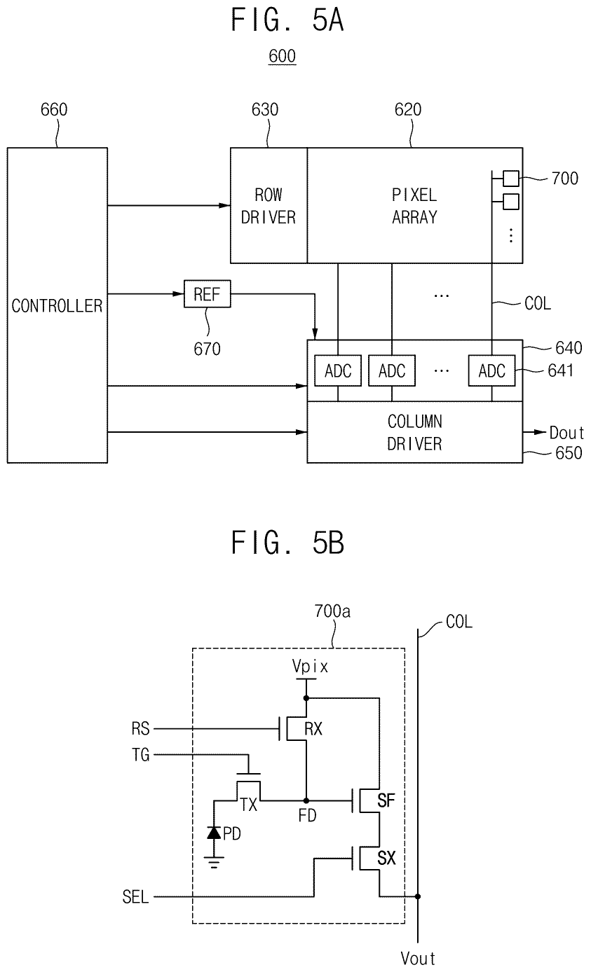

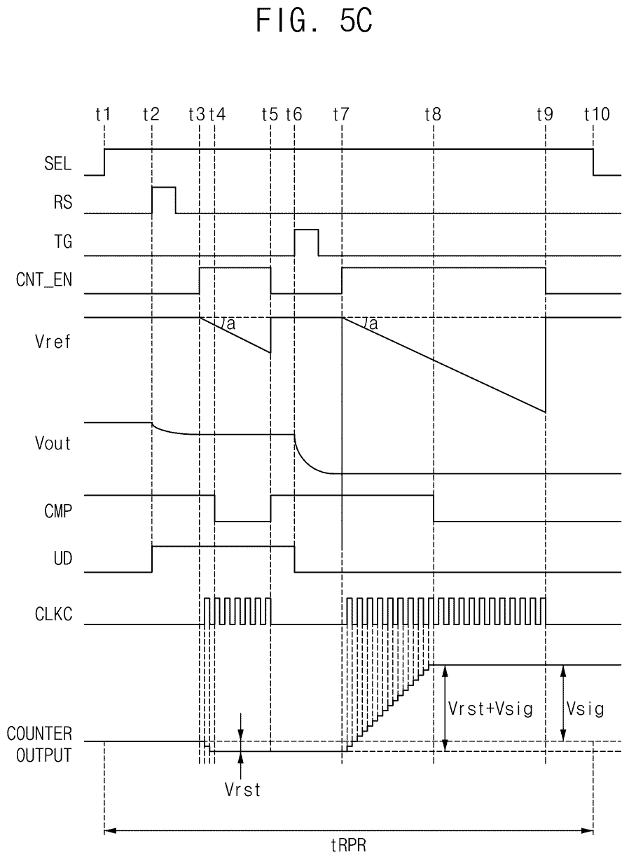

Referring to FIG. 1, a pixel PX of an image sensor may include a photoelectric conversion region (e.g., photodiode) PD, a floating diffusion region FD, a transfer gate TG, and a pixel transistor PXT formed using (or provided with) the semiconductor substrate 110. Only some components for illustrating example embodiments are shown in FIG. 1 for convenience of illustration and description, and more detailed configurations of the image sensor and pixels will be further described below with reference to FIGS. 5A through 12B.

The photoelectric conversion region PD, such as a photodiode, may be disposed in a lower portion of the semiconductor substrate 110, and the floating diffusion region FD may be disposed in an upper portion of the semiconductor substrate 110. For example, if the semiconductor substrate 110 has a P-conductive type, the photoelectric conversion region PD and the floating diffusion region FD may have an N-conductive type. The semiconductor substrate 110 and the photoelectric conversion region PD may form a PN junction. The photoelectric conversion region PD may be a photodiode.

The transfer gate TG may include a lower transfer gate 150 disposed on the semiconductor substrate 110 and an upper transfer gate 151 disposed on the lower transfer gate 150. While FIG. 1 illustrates that the lower transfer gate 150 is a vertical transfer gate including a horizontal portion disposed on the upper surface 110F1 of the semiconductor substrate 110 and a vertical portion extending into the interior of the semiconductor substrate 110, embodiments are not limited thereto. According to example embodiments, the lower transfer gate 150 may be implemented as a planar type that does not include the vertical portion.

The pixel transistor PXT may include a first source/drain region SD1, a second source/drain region SD2, and a pixel gate PG. For example, if the semiconductor substrate 110 is a P-conductive type, the first source/drain region SD1 and the second source/drain region SD2 may have an N-conductive type. The pixel transistor PXT may correspond to a reset transistor RX, a selection transistor SX, or a source follower transistor SF, as will be described below.

The first source/drain region SD1 and the second source/drain region SD2 may be disposed in an upper portion of the semiconductor substrate 110, and the pixel gate PG may be disposed on the semiconductor substrate 110 between the first source/drain region SD1 and the second source/drain region SD2. The pixel gate PG may include a lower pixel gate 140 disposed on the semiconductor substrate 110 and an upper pixel gate 141 disposed on the lower pixel gate 140. While the lower pixel gate 140 of a planar type is shown in FIG. 1, according to example embodiments, the lower pixel gate 140 may be implemented as a vertical transfer gate including a horizontal portion and a vertical portion which are similar to the lower transfer gate 150 shown in FIG. 1.

A gate insulating layer 142 may be disposed on the upper surface of the semiconductor substrate 110, and gate structures such as the transfer gate TG and the pixel gate PG may be disposed on the gate insulating layer 142. Components such as the pixel transistor and the floating diffusion region FD may be isolated from each other by device separators STI disposed in the upper portion of the semiconductor substrate 110.

Respective vertical contacts CA may be disposed on the upper pixel gate 141 and the upper transfer gate 151 to which signals are applied. The upper pixel gate 141 and the upper transfer gate 151 may be connected via the vertical contacts CA to metal lines MPT disposed in a metal layer ML. In addition, the junctions SD1, SD2 and FD (e.g., junctions provided by the floating diffusion region PD and the source/drain regions SD1 and SD2) to which a voltage is applied or from which a voltage is detected may be connected to the metal lines MPT disposed in the metal layer ML via vertical contacts CB.

For example, the upper pixel gate 141 and the upper transfer gate 151 may be doped with charge carrier impurities. The doping concentration of the upper pixel gate 141 may be substantially the same as that of the upper transfer gate 151. In semiconductor technology, if a semiconductor contains both p-type and n-type impurities, the conductivity-type of the semiconductor will be determined by which type of impurity is in greater concentration. Therefore, if a semiconductor has both p-type and n-type impurities, the net conductivity type will be determined by the dominant impurity concentration. As used herein, a semiconductor region of a “first conductivity-type” denotes that the dominant impurities in the semiconductor region is (or are) a first conductivity-type impurity, and a “concentration of the first conductivity-type” in the semiconductor region (or a “doping concentration”) refers the net concentration of the impurities in the semiconductor region (i.e., (the amount of first conductivity-type impurities minus the amount of second conductivity-type impurities)/the volume of the semiconductor region).

FIG. 2 illustrates a gate GT of the planar type corresponding to the pixel gate PG and/or the transfer gate TG. As described above with reference to FIG. 1, the gate GT may include a lower gate GB and an upper gate GU. The lower gate GB corresponds to the lower pixel gate 140 and/or the lower transfer gate 150 of FIG. 1, and the upper gate GU corresponds to the upper pixel gate 141 and/or the upper transfer gate 151 of FIG. 1.

Referring to FIG. 2, a size h2 in the horizontal direction, which is parallel to the upper surface of the semiconductor substrate 110, of the upper gate GU may be smaller than a size h1 in the horizontal direction of the lower gate GB. For example, referring again to FIG. 1, the size (corresponding to h2) in the horizontal direction of the upper transfer gate 151 may be smaller than the size (corresponding to h1) in the horizontal direction of the lower transfer gate 150, and the size (corresponding to h2) in the horizontal direction of the upper pixel gate 141 may be smaller than the size (corresponding to h1) in the horizontal direction of the lower pixel gate 140.

In an example embodiment, a thickness t2 in the vertical direction, which is perpendicular to the upper surface of the semiconductor substrate 110, of the upper gate GU may be larger than a thickness t1 in the vertical direction of the lower gate GB. For example, referring again to FIG. 1, the thickness (corresponding to t2 in FIG. 2) in the vertical direction of the upper transfer gate 151 may be larger than the thickness(corresponding to t1 in FIG. 2) in the vertical direction of the lower transfer gate 150, and the thickness (corresponding to t2 in FIG. 2) in the vertical direction of the upper pixel gate 141 may be larger than the thickness (corresponding to t1 in FIG. 2) in the vertical direction of the lower pixel gate 140.

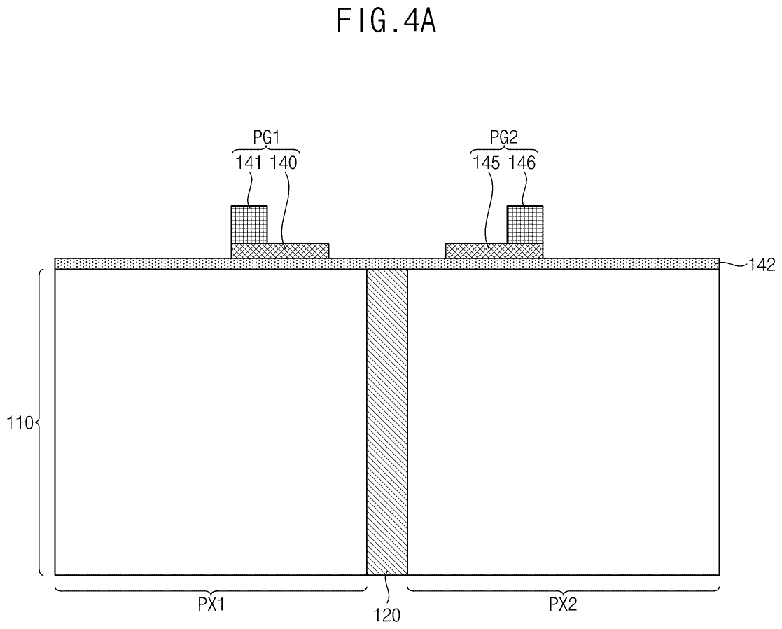

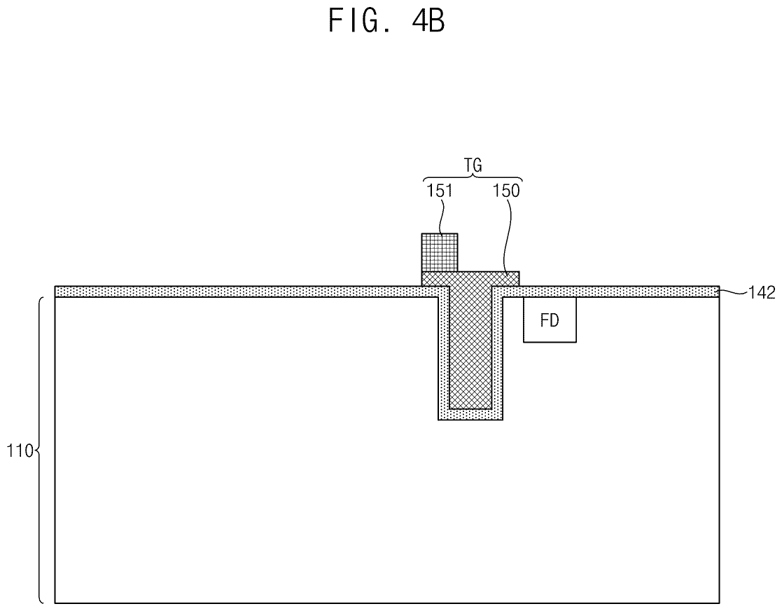

The position of the upper gate GU in the horizontal direction on the lower gate GB may be determined by considering the relationship to neighboring components. Example embodiments of the arrangement of the upper gate GU on the lower gate GB will be described below with reference to FIGS. 4A and 4B.

As such, the pixel PX of the image sensor according to example embodiments may adopt the dual-gate structure including the lower gate GB and the upper gate GU having the smaller horizontal size than the lower gate GB, thereby reducing the coupling capacitance between the gate and other components and improving the electrical characteristics of the pixel and the image sensor.

Furthermore, the pixel PX of the image sensor according to example embodiments may efficiently improve the electrical characteristics of the pixel and image sensor without excessive changes to the existing layout design by changing only the size and position of the upper gate GU while keeping the layout of the lower gate GB unchanged.

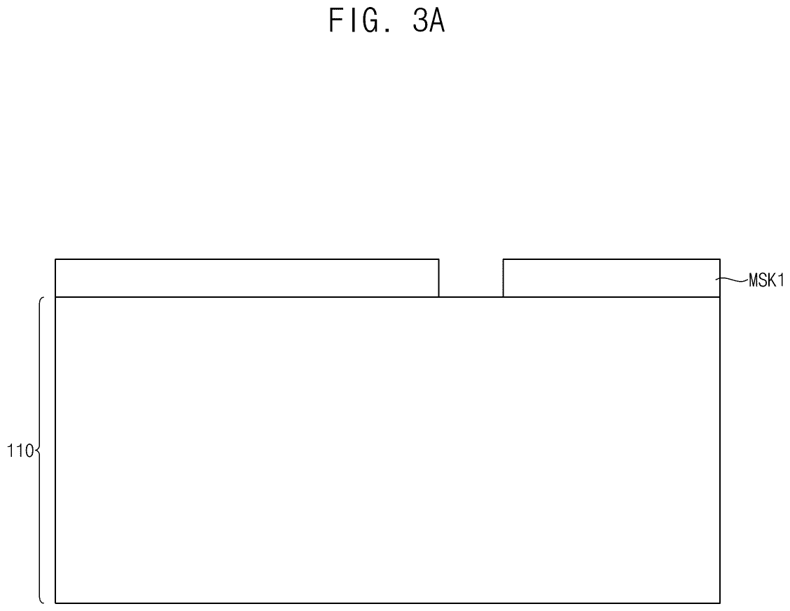

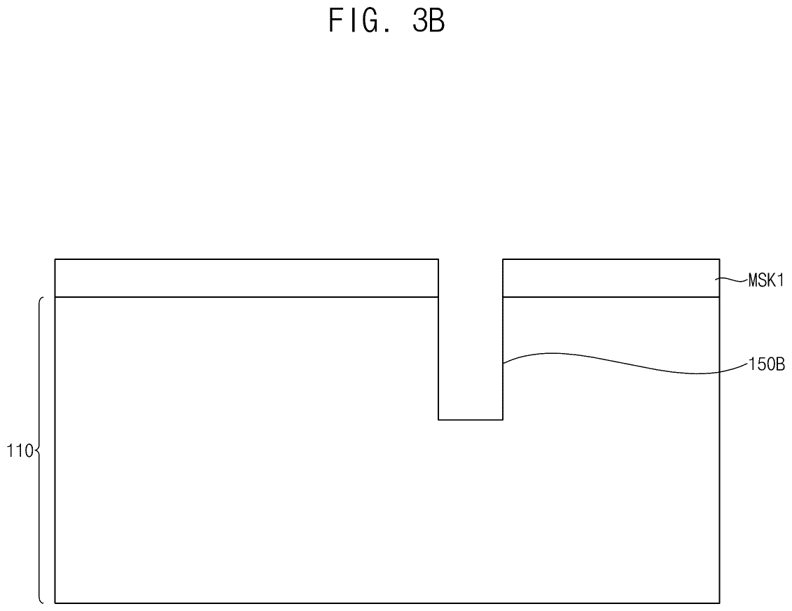

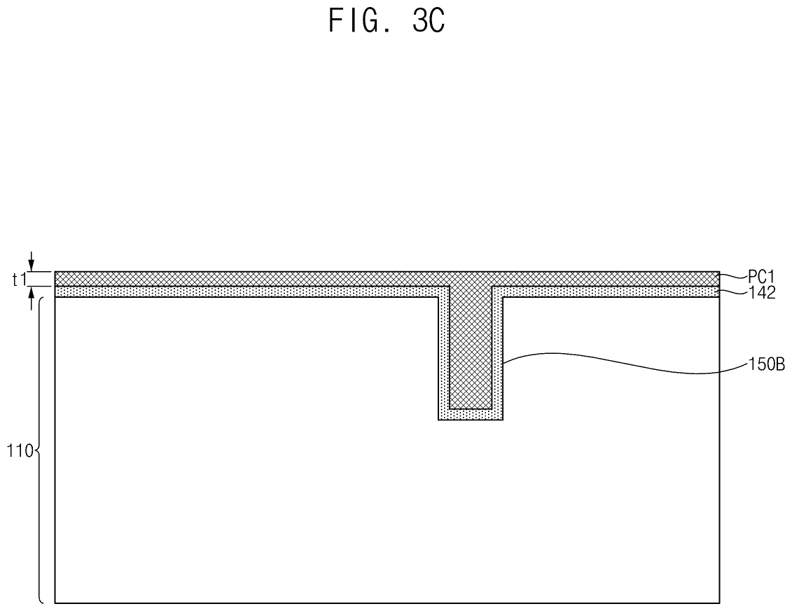

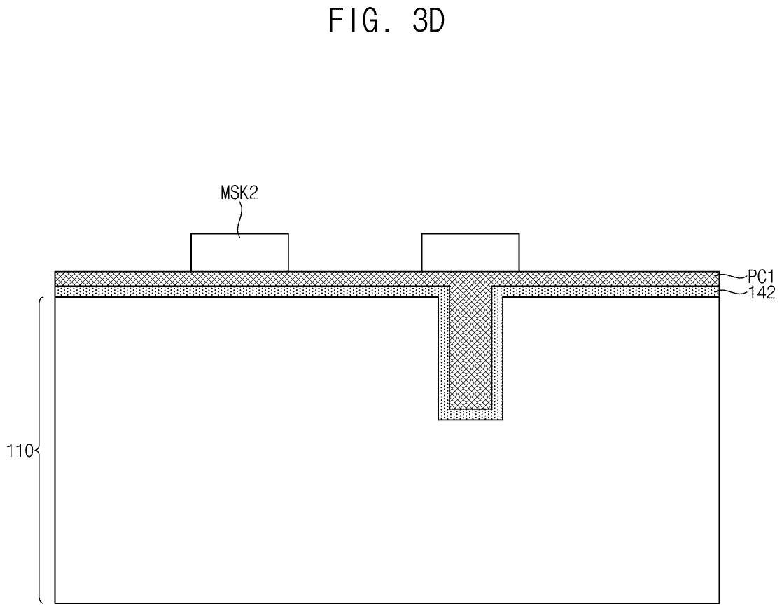

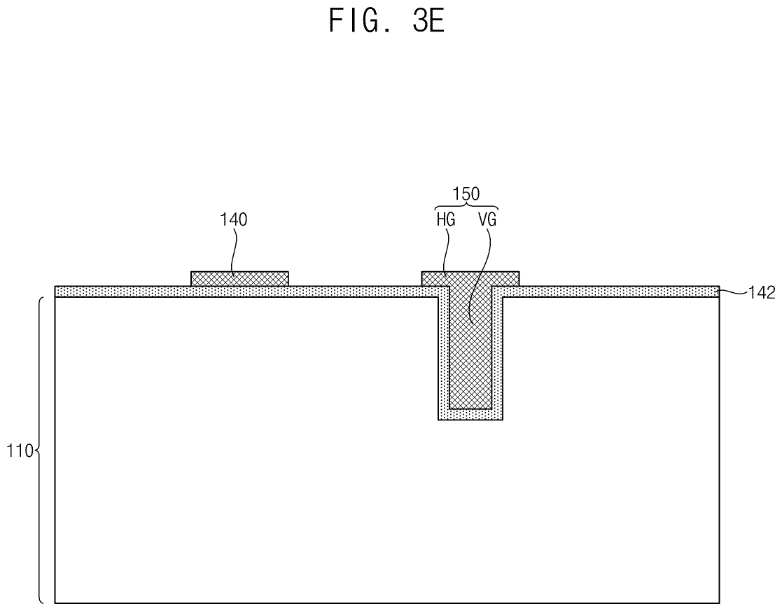

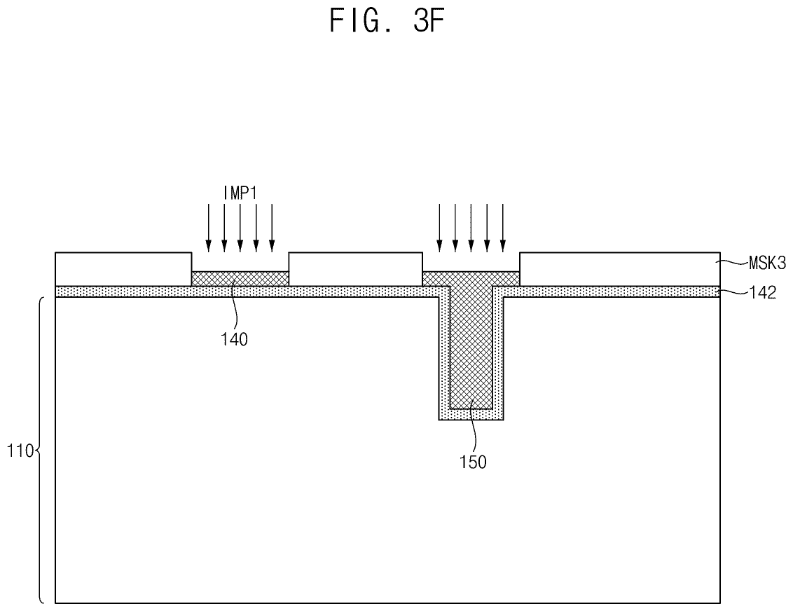

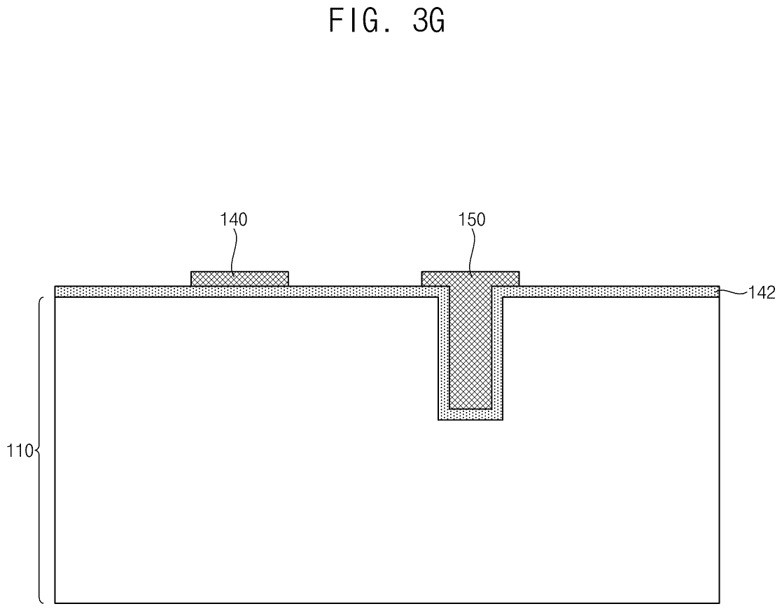

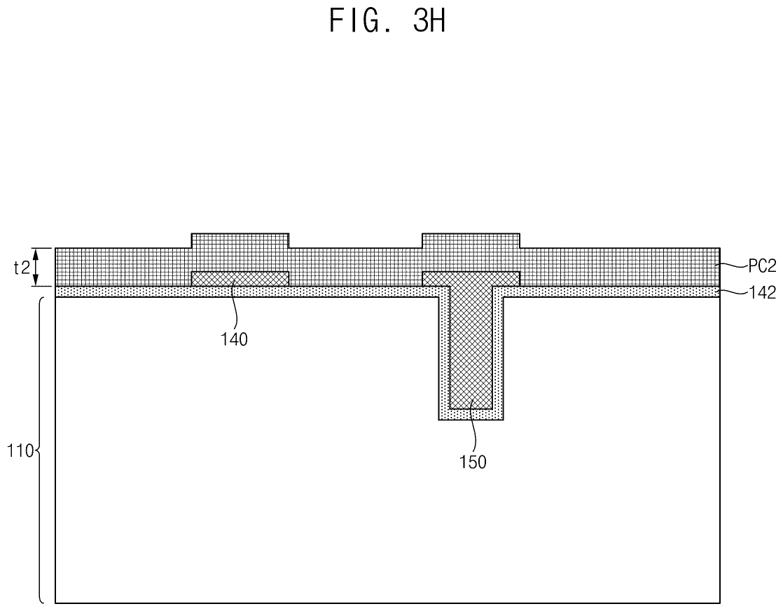

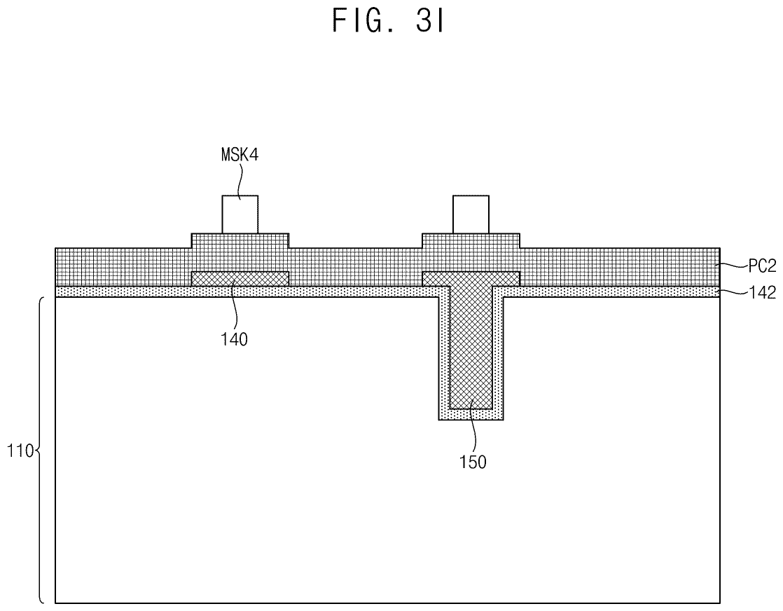

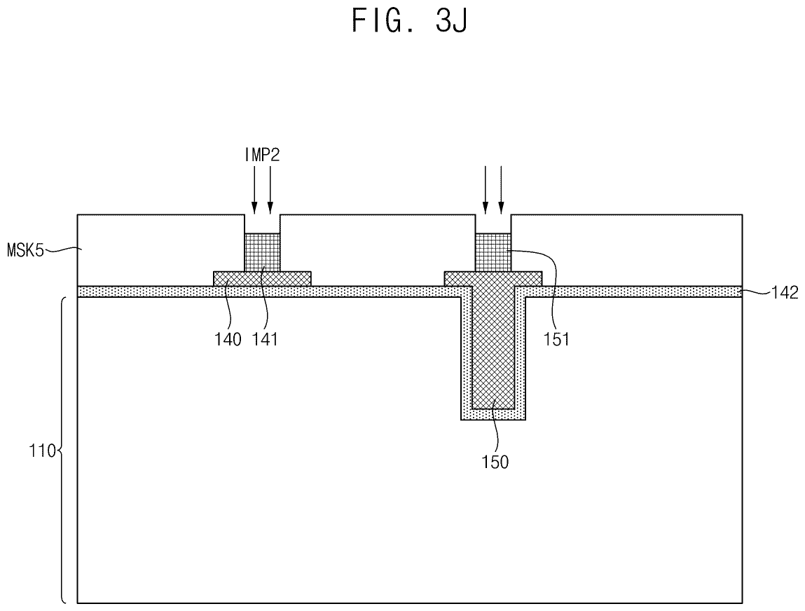

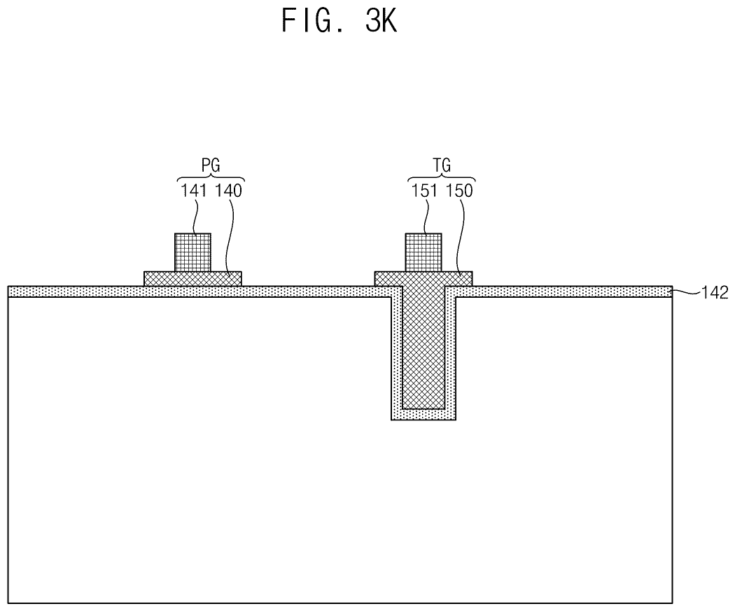

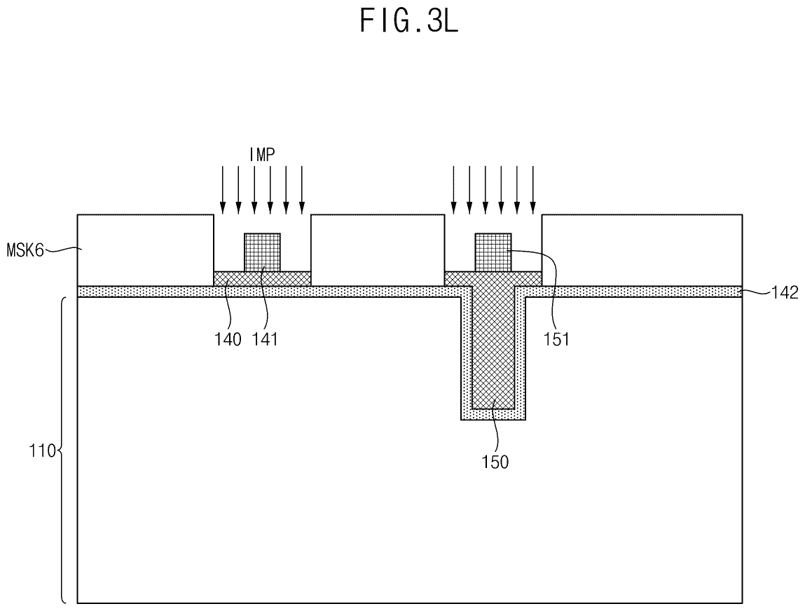

FIGS. 3A through 3L are cross-sectional diagrams illustrating a method of manufacturing an image sensor according to example embodiments.

Referring to FIGS. 3A and 3B, a first mask MSK1 may be formed on the upper surface (i.e., the first surface 110F1 of FIG. 1) of the semiconductor substrate 110, and an opening 150B corresponding to a vertical portion of the lower transfer gate 150 extending from the upper surface of the semiconductor substrate 110 to the interior of the semiconductor substrate 110 may be formed using the first mask MSK1 as an etch mask. Thereafter, the first mask MSK1 may be removed.

Referring to FIG. 3C, a gate insulating layer 142 may be formed on the upper surface of the semiconductor substrate 110 and the inner wall of the opening 150B, and a first poly layer PC1 may be formed on the gate insulating layer 142 by performing a first deposition process. The thickness t1 of the first poly layer PC1 may be set as small as possible within a range that may sufficiently fill the opening 150B. The horizontal portion of the lower transfer gate 150 disposed on the upper surface of the semiconductor substrate 110 and the vertical portion extending into the interior of the semiconductor substrate 110 may be formed simultaneously by the first deposition process. The thickness t1 of the first poly layer PC1 may correspond to the thickness in the vertical direction of the lower gate GB described with reference to FIG. 2.

Referring to FIGS. 3D and 3E, a second mask MSK2 may be formed on the first poly layer PC1, and the second mask MSK2 may be used as an etch mask to pattern the first poly layer PC1 to form the lower pixel gate 140 and the lower transfer gate 150. In this way, the lower pixel gate 140 and the lower transfer gate 150 may be formed simultaneously by patterning the first poly layer PC1 formed by the first deposition process. As described above, the lower transfer gate 150 may include a horizontal portion HG disposed on an upper surface of the semiconductor substrate 110 and a vertical portion VG extending into the interior of the semiconductor substrate 110.
For example, the upper surfaces of the lower transfer gate 150 and the lower pixel gate 140 may be substantially coplanar.

Referring to FIG. 3F, a third mask MSK3 may be formed on the gate insulating layer 142, and a first ion implantation process IMP1 may be performed using the third mask MSK3 as an ion implantation mask to simultaneously dope the lower pixel gate 140 and the lower transfer gate 150. The third mask MSK3 may then be removed to form the impurity-doped lower pixel gate 140 and lower transfer gate 150, as shown in FIG. 3G.

Referring to FIG. 3H, a second deposition process may be performed to form a second poly layer PC2 on the gate insulating layer 142, the lower pixel gate 140, and the lower transfer gate 150. The thickness t2 of the second poly layer PC2 may be set to be as small as possible within a range in which the vertical contact CA of FIG. 1 may be formed. The thickness t2 of the second poly layer PC2 may correspond to the thickness in the vertical direction of the upper gate GB described with reference to FIG. 2. As shown in FIG. 1, the vertical contacts CA may be formed by penetrating a portion of the upper pixel gate 141 and the upper transfer gate 151. For example, the thickness t2 of the second poly layer PC2 may be set to be larger than the thickness of the first poly layer PC1.

Referring to FIGS. 3I and 3J, a fourth mask MSK4 may be formed on the second poly layer PC2, and the fourth mask MSK4 may be used as an etch mask to pattern the second poly layer PC2 to form the upper pixel gate 141 and the upper transfer gate 151. In this way, the upper pixel gate 141 and the upper transfer gate 151 may be formed simultaneously by patterning the second poly layer PC2 that is formed by the second deposition process. For example, the upper surfaces of the upper transfer gate 151 and the upper pixel gate 141 may be substantially coplanar.

Subsequently, the fourth mask MSK4 may be removed and a fifth mask MSK5 may be formed on the gate insulating layer 142, the lower pixel gate 140, and the lower transfer gate 150. A second ion implantation process IMP2 using the fifth mask MSK5 as an ion implantation mask may be performed to simultaneously dope the upper pixel gate 141 and the upper transfer gate 151. The fifth mask MSK5 may then be removed to form the impurity-doped pixel gate PG and transfer gate TG as shown in FIG. 3K.

As such, the vertical portion extending into the semiconductor substrate 110 of the lower transfer gate 150 may be efficiently doped by the first ion implantation process IMP1 of FIG. 3F. The upper transfer gate 151 for the vertical contacts CA may then be efficiently doped by the second ion implantation process IMP2 of FIG. 3J. According to example embodiments, at least one of the impurity type and the doping concentration of the second ion implantation process IMP2 may be different from a corresponding one of the impurity type and the doping concentration of the first ion implantation process IMP1.

In an example embodiment, as shown in FIG. 3L, a sixth mask MSK6 may be formed after forming the upper pixel gate 141 and the upper transfer gate 151. an ion implantation process IMP using the sixth mask MSK as an ion implantation mask may be performed to simultaneously dope the lower pixel gate 140, the upper pixel gate 141, the lower transfer gate 150, and the upper transfer gate 151. Accordingly, the doping concentration of the upper pixel gate 141 may be substantially the same as that of the upper transfer gate 151.

FIGS. 4A and 4B are diagrams illustrating example embodiments of arrangement of upper gates in pixels of an image sensor according to example embodiments.

In an example embodiment, the upper gate GU of FIG. 2 may be disposed on an end portion that is farther from the pixel isolator for isolating the pixel from neighboring pixels, among two end portions in the horizontal direction of the lower pixel gate GB.

For example, as shown in FIG. 4A, a pixel isolator 120 for isolating the first pixel PX1 and the second pixel PX2 may be disposed inside the semiconductor substrate 110, and the pixel gates PG1 and PG2 may be disposed adjacent to the pixel isolator 120. In this case, the upper pixel gate 141 of the first pixel PX1 may be disposed on the end portion that is farther from the pixel isolator 120, among the two end portions in the horizontal direction of the lower pixel gate 140. Further, the upper pixel gate 146 of the second pixel PX2 may be disposed on the end portion that is farther from the pixel isolator 120, among the two ends of the lower pixel gate 145. Thus, by reducing the opposing areas of the sidewalls of the lower pixel gates 140 and 145 that are relatively close together and spacing the upper pixel gates 141 and 146 that have relatively large opposing areas, the coupling capacitance between the pixel gates PG1 and PG2 may be reduced. By reducing the coupling capacitance, interference of signals and/or voltages associated with the pixel gates PG1 and PG2 may be reduced and electrical characteristics may be improved.

For example, in a horizontal direction being parallel to the upper surface of the semiconductor substrate 110, a first distance between upper end portions of the first and second pixel gates PG1 and PG2 may be different from a second distance between lower end portions of the first and second pixel gates PG1 and PG2.

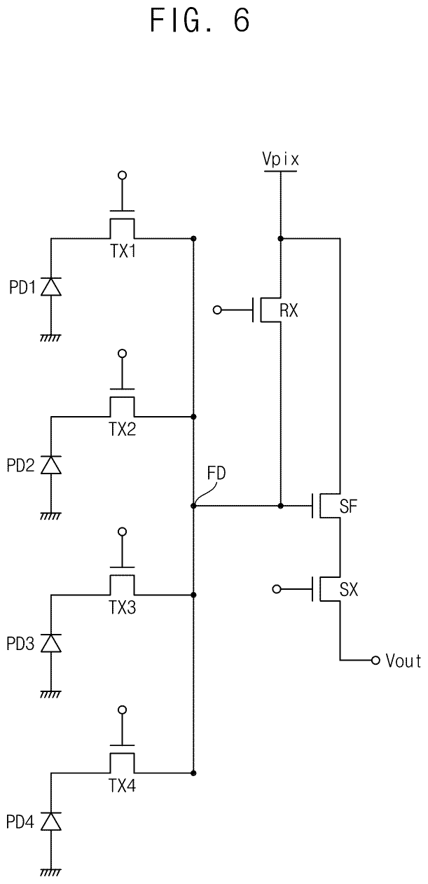

For example, the lower pixel gate 145 may have a first portion (or upper portion) and a second portion (or lower portion) in a vertical direction, the first portion may be one of the upper pixel gates 141 and 146, and the second portion may be one of the lower pixel gates 140 and 145. In a plan view, the first portion may be more spaced apart from the pixel isolator 120 than the second portion. The pixel gates PG1 and PG2 may be gate electrodes of source follower transistors (indicated by SF in FIGS. 5B and 6) of two adjacent pixels.

In an example embodiment, as shown in FIG. 4B, the upper transfer gate 151 may be disposed on the end portion that is farther from the floating diffusion region FD, among the two portions in the horizontal direction of the lower transfer gate 150. Thus, the coupling capacitance between the floating diffusion region FD and the transfer gate TG may be reduced, and the conversion gain of the floating diffusion region FD may be increased.

FIG. 5A is a block diagram illustrating an image sensor according to example embodiments.

Referring to FIG. 5A, an image sensor 600 may include a pixel array 620, a row driver 630, an analog-to-digital conversion circuit 640, a column driver 650, a controller 660, and/or a reference signal generator (REF) 670.

The pixel array 620 includes a plurality of pixels 700 coupled to column lines COL, respectively. For example, each of the plurality of pixels 700 may be coupled to a respective column line COL. The plurality of pixels 700 are configured to sense incident light to generate analog signals through the column lines COL. The plurality of pixels 700 may be arranged in matrix form with a plurality of rows and a plurality of columns. The pixel array 620 may have a structure in which a plurality of unit patterns are arranged repeatedly in a first horizontal direction and a second horizontal direction that is perpendicular to the first horizontal direction.

The row driver 630 may be coupled to the rows of the pixel array 620 and may be configured to generate signals for driving the rows. For example, the row driver 630 may drive (e.g., control or select) the pixels in the pixel array 620 row by row. For example, the row driver 630 may control the pixels in the pixel array 620 row by row such that one of rows included in the pixel array 20 is selected by providing an activated row selection signal SEL to the selected row of the pixel array 620 as described later with reference to FIGS. 5A, 5B, and 5C.

The analog-to-digital conversion circuit 640 may be coupled to the columns of the pixel array 620 and may be configured to convert the analog signals from the pixel array 20 to digital signals. As illustrated in FIG. 5A, the analog-to-digital conversion circuit 640 may include a plurality of analog-to-digital converters (ADC) 641 to perform analog-to-digital conversion of the analog signals output from the column lines COL in parallel or simultaneously.

The analog-to-digital conversion circuit 640 may include a correlated double sampling (CDS) unit. In some example embodiments, the CDS unit may perform an analog double sampling by extracting a valid image component based on a difference between an analog reset signal and an analog image signal. In some example embodiments, the CDS unit may perform a digital double sampling by converting the analog reset signal and the analog image signal to two digital signals and extracting a difference between the two digital signals as the valid image component. In some example embodiments, the CDS unit may perform a dual CDS by performing both the analog double sampling and digital double sampling.

The column driver 650 may be configured to output the digital signals from the analog-to-digital conversion circuit 40 sequentially as output data Dout.

The controller 660 may be configured to control the row driver 30, the analog-to-digital conversion circuit 640, the column driver 650, and/or the reference signal generator 670. The controller 660 may provide control signals such as clock signals, timing control signals, etc. applied to the operations of the row driver 630, the analog-to-digital conversion circuit 640, the column driver 650, and/or the reference signal generator 670. The controller 660 may include a control logic circuit, a phase-locked loop, a timing control circuit, a communication interface circuit, etc. In one embodiment, the controller 660 and the pixel array 620 may be embodied as a single semiconductor chip. In another embodiment, the controller 660 and the pixel array 620 may each be embodied as separate semiconductor chips and electrically connected to each other.

The reference signal generator 670 may generate a reference signal or a ramp signal that increases or decreases gradually (e.g., with a slope), and provide the ramp signal to the analog-to-digital conversion circuit 40.

FIG. 5B is a circuit diagram illustrating an example of a unit circuit included in an image sensor according to example embodiments.

Referring to FIG. 5B, a unit pixel 700a may include a photo-sensitive element such as a photodiode PD, and a readout circuit including a transfer transistor TX, a reset transistor RX, a source follower transistor SF, and/or a selection transistor SX.

The photo-charges generated in the photodiode PD may be transferred to a floating diffusion node FD through the transfer transistor TX. For example, the transfer transistor TX may be turned on in response to a transfer control signal TG, when the transfer control signal TG has a first level (e.g., a logic high level), and the photocharges generated in the photodiode PD may be transferred to the floating diffusion region FD through the turned-on transfer transistor TX.

The source follower transistor SF is configured to function as a source follower amplifier that amplifies a signal corresponding to the charge on the floating diffusion node FD. The selection transistor SX may transfer the pixel signal Vpix to a column line COL in response to a selection signal SEL.

The floating diffusion node FD may be configured to be reset by the reset transistor RX. For example, the reset transistor RX may discharge the floating diffusion node FD in response to a reset signal RS for correlated double sampling (CDS).

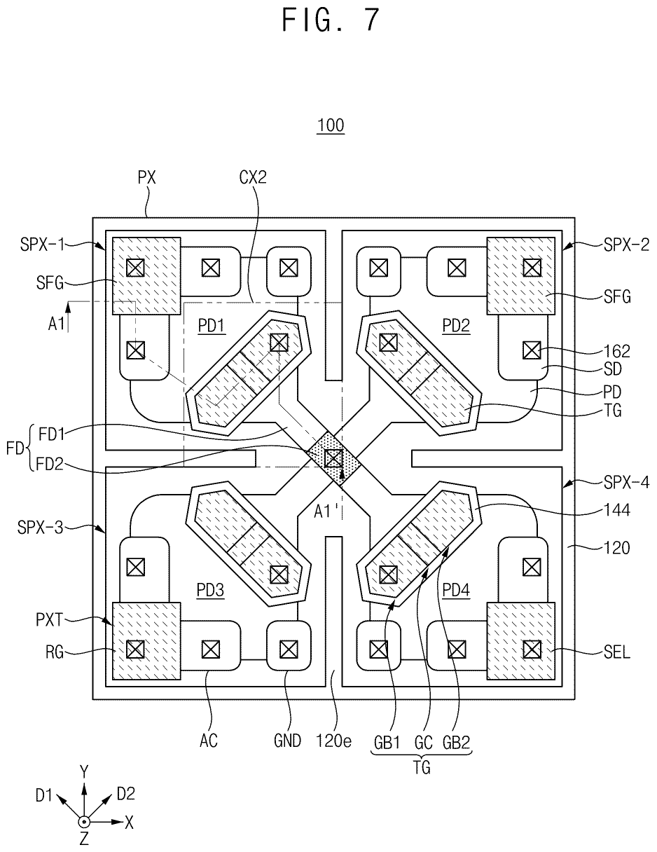

The reset transistor RX, the source follower transistor SF, and the selection transistor SX may be distributed in a plurality of pixels or sub-pixels, as will be described below with reference to FIG. 7. The pixel transistor PXT described above may correspond to the reset transistor RX, the source follower transistor SF, or the selection transistor SX.

FIG. 5B illustrates the unit pixel 700a of the four-transistor configuration including the four transistors TX, RX, SF, and SX. The configuration of the unit pixel may be variously changed, and the pixel structure is not limited to that of FIG. 5B.

FIG. 5C is a timing diagram illustrating an example operation of an image sensor according to example embodiments.

FIG. 5C illustrates a sensing period tRPR corresponding to a sensing operation of a pixel. The sensing operation may be performed simultaneously with respect to pixels corresponding to the same transfer control signal TG.

Referring to FIGS. 5A, 5B, and 5C, at a time t1, the row driver 630 may select one of rows included in the pixel array 20 by providing an activated row selection signal SEL to the selected row of the pixel array 620.

At a time t2, the row driver 630 may provide an activated reset control signal RS to the selected row, and the controller 60 may provide an up-down control signal UD having a logic high level to a counter included in the ADC 641. From the time t2, the pixel array 620 may output a first analog signal corresponding to a reset component Vrst as the pixel power voltage Vpix.

At a time t3, the controller 660 may provide a count enable signal CNT_EN having a logic high level to the reference signal generator 670, and the reference signal generator 670 may start to decrease the reference signal Vref at the constant rate, e.g., a slope of ‘a’. The controller 660 may provide a count clock signal CLKC to the counter, and the counters may perform down-counting from zero in synchronization with the count clock signal CLKC.

At a time t4, a magnitude of the reference signal Vref may become smaller than a magnitude of the pixel power voltage Vpix, and a comparator included in the ADC 641 may provide a comparison signal CMP having a logic low level to the counter so that the counter stops performing the down-counting. At the time t4, a counter output of the counter may be the first counting value that corresponds to the reset component Vrst. In the example of FIG. 5C, the counter output of the counter at the time t4 may be −2.

At a time t5, the controller 660 may provide the count enable signal CNT_EN having a logic low level to the reference signal generator 670, and the reference signal generator 670 may stop generating the reference signal Vref.

A period from the time t3 to the time t5 corresponds to the maximum time for detecting the reset component Vrst. A length of the period from the time t3 to the time t5 may be determined as a certain number of the count clock signal CLKC according to a characteristic of the image sensor 600.

At a time t6, the row driver 630 may provide an activated transfer control signal TG (e.g., the transfer control signal TG having a logic high level) to the selected row, and the controller 660 may provide the up-down control signal UD having a logic low level to the counter. From the time t6, the pixel array 620 may output a second analog signal AS2 corresponding to a detected incident light Vrst+Vsig as the pixel power voltage Vpix.

At a time t7, the controller 660 may provide the count enable signal CNT_EN having a logic high level to the reference signal generator 670, and the reference signal generator 670 may start to decrease the reference signal Vref at the same constant rate as at the time t3, e.g., a slope of ‘a’. The comparator may provide the comparison signal CMP having a logic high level to the counter since the pixel power voltage Vpix is smaller than the reference signal Vref. The controller 660 may provide the count clock signal CLKC to the counter, and the counter may perform an up-counting from the first counting value, which corresponds to the reset component Vrst, in synchronization with the count clock signal CLKC.

At a time t8, the magnitude of the reference signal Vref may become smaller than the magnitude of the pixel power voltage Vpix, and the comparator may provide the comparison signal CMP having a logic low level to the counter so that the counter stops performing the up-counting. At the time t8, the counter output of the counter may correspond to a difference between the first analog signal representing the reset component Vrst (e.g., −2 in the example of FIG. 5C) and the second analog signal representing the detected incident light Vrst+Vsig (e.g., 17 in the example of FIG. 5C). The difference may be an effective intensity of incident light Vsig (e.g., 15 in the example of FIG. 5C). The counter may output the effective intensity of incident light Vsig as the digital signal.

At a time t9, the controller 660 may provide the count enable signal CNT_EN having a logic low level to the reference signal generator 670, and the reference signal generator 670 may stop generating the reference voltage Vref.

A period from the time t7 to the time t9 corresponds to the maximum time for detecting the detected incident light Vrst+Vsig. A length of the period from the time t7 to the time t9 may be determined as a certain number of the count clock signal CLKC according to a characteristic of the image sensor 600.

At a time t10, the row driver 630 may provide a deactivated row selection signal SEL (e.g., the row selection signal having a low level) to the selected row of the pixel array 620, and the counter may reset the counter output to zero.

After that, the image sensor 600 may repeat the above described operations on each row to generate the digital signals row by row.

The configuration and the sensing operation of an image sensor have been described with reference to FIGS. 5A, 5B and 5C, but embodiments are not limited thereto.

FIG. 6 is a diagram illustrating an example embodiment of a configuration of pixels and a readout circuit according to example embodiments.

FIG. 6 illustrates four sub-pixels and a readout circuit shared by the four sub-pixels. The sub-pixels may each include photoelectric conversion regions PD1, PD2, PD3, and PD4 and transfer transistors TX1, TX2, TX3, and TX4. The readout circuit may include a reset transistor RX, a selection transistor SX, and a source follower transistor SF. The reset transistor RX may include a reset gate RG (see FIG. 7), the selection transistor SX may include a selection gate SEL (see FIG. 7), the source follower transistor SF may include a source follower gate SFG (see FIG. 7), and each of the transfer transistors TX1, TX2, TX3, and TX4 may include a transfer gate TG (see FIG. 7).

The photoelectric conversion regions PD1, PD2, PD3, and PD4 may each be connected to a floating diffusion region FD via the transfer transistors TX1, TX2, TX3, and TX4. The photoelectric conversion regions PD1, PD2, PD3, and PD4 may generate and accumulate photoelectric charges in proportion to the amount of light incident from the outside (e.g., external to the image sensor), and may be photodiodes, phototransistors, photogates, pinned photodiodes, and combinations thereof.

The transfer gate TG may transfer the photocharges generated in the photoelectric conversion regions PD1, PD2, PD3, and PD4 to the floating diffusion region FD. The floating diffusion region FD may receive and cumulatively store the charge generated by the photoelectric conversion regions PD1, PD2, PD3, and PD4. The source follower transistor SF may be controlled according to the amount of photocharges accumulated in the floating diffusion region FD.

The reset transistor RX may periodically reset the accumulated charges in the floating diffusion region FD. The drain electrode of the reset transistor RX is connected to the floating diffusion region FD and the source electrode is connected to the power supply voltage Vpix. When the reset transistor RX is turned on, the power supply voltage Vpix connected to the source electrode of the reset transistor RX is transferred to the floating diffusion region FD. When the reset transistor RX is turned on, the charge accumulated in the floating diffusion region FD may be discharged to reset the floating diffusion region FD.

The source follower transistor SF functions as a source follower buffer amplifier, amplifies the potential change in the floating diffusion region FD and outputs a current corresponding to the potential change to the output line VOUT.

The selection transistor SX may select a plurality of pixels on a row-by-row basis. When the selection transistor SX is turned on, the current generated by the source follower transistor SF may be transferred to the output line VOUT.

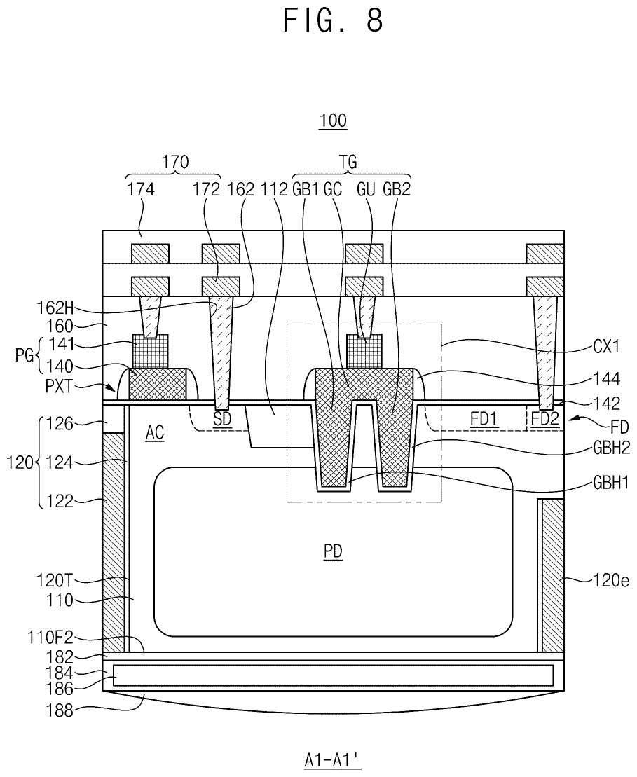

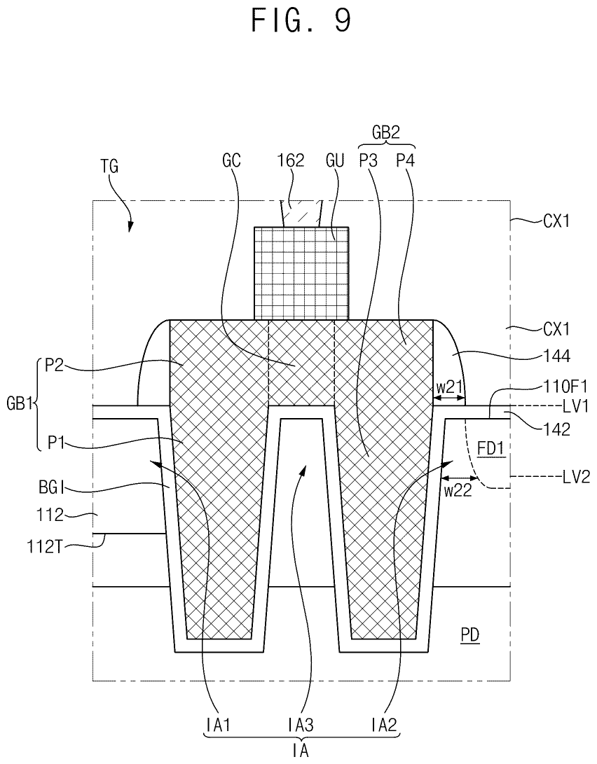

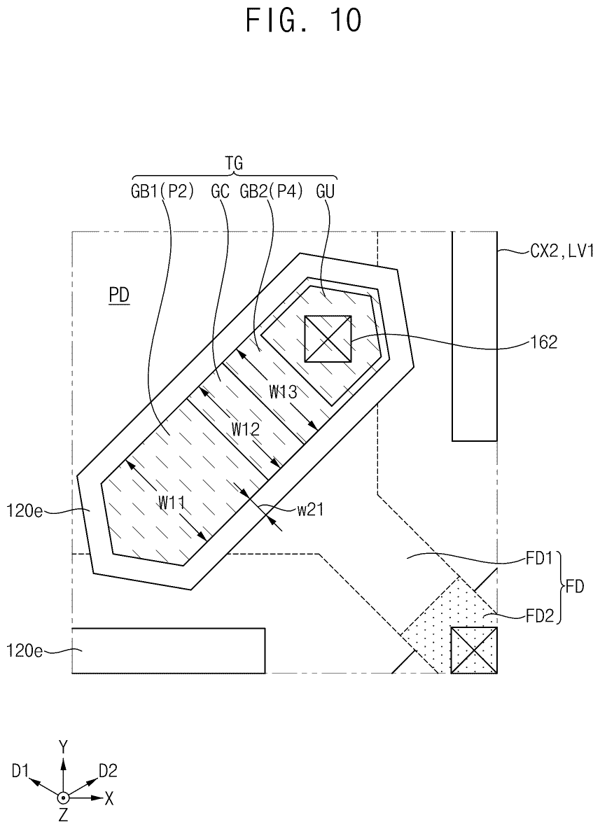

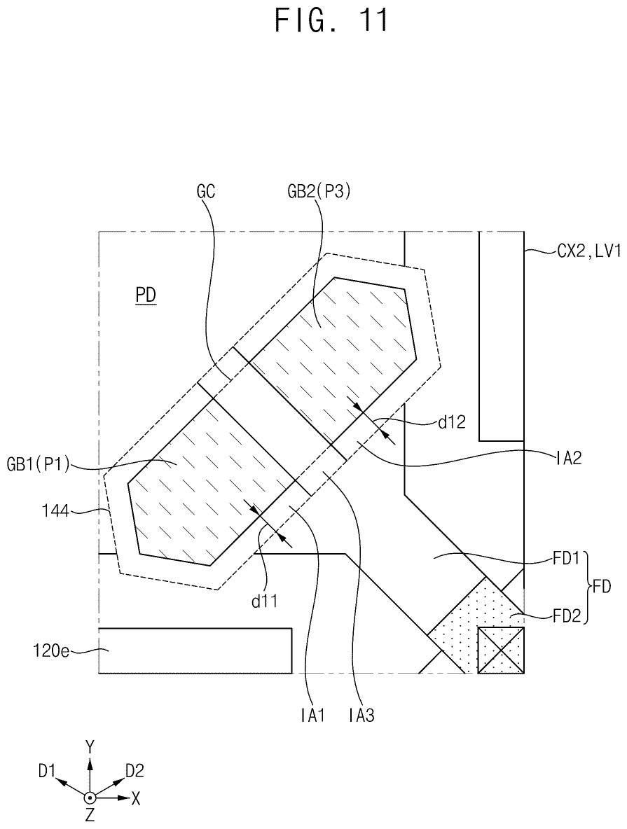

FIG. 7 is a diagram (e.g., plan view) illustrating an example embodiment of a layout of an image sensor according to example embodiments, and FIG. 8 is a cross-sectional diagram illustrating a vertical structure along a line A1-A1′ in FIG. 7. FIG. 9 is a diagram illustrating an enlarged view of a portion CX1 of FIG. 8. FIG. 10 is a diagram (e.g., plan view) drawn along a horizontal cross-section at the second vertical level of FIG. 8 and illustrating a portion CX2 of FIG. 7. FIG. 11 is a diagram (e.g., plan view) drawn along a horizontal cross-section at the second vertical level of FIG. 8 and illustrating a plan view of the portion CX2 of FIG. 7.

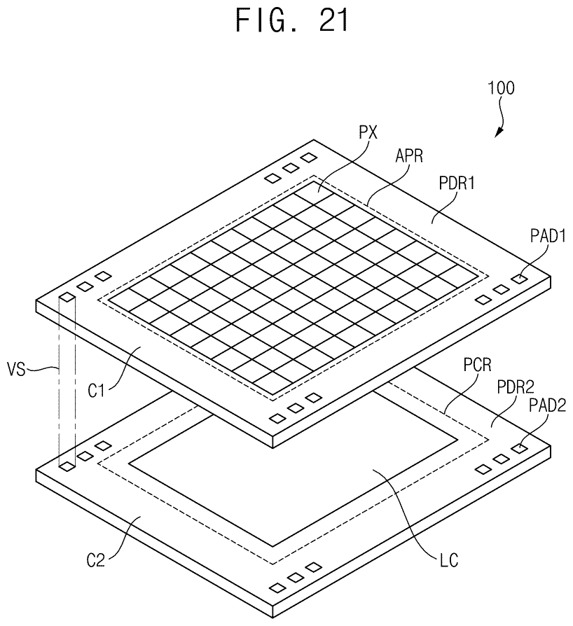

Referring to FIGS. 7 through 11, an active pixel region APR of an image sensor (see FIG. 21) includes a plurality of pixels PX, and a plurality of photoelectric conversion regions PD may each be disposed within the plurality of pixels PX. In the active pixel region APR, the plurality of pixels PX may be arranged in a matrix shape in columns and rows along a first direction X parallel to the upper surface of the semiconductor substrate 110 and a second direction Y perpendicular to the first direction and parallel to the upper surface of the semiconductor substrate 110.

The semiconductor substrate 110 may include a first surface (i.e., an upper surface) 110F1 and a second surface (i.e., a lower surface) 110F2 that are opposite each other. Herein, for convenience of illustration and description, the surface of the semiconductor substrate 110 on which the color filter 186 is disposed is referred to as the second surface 110F2 and the surface opposite to the second surface 110F2 is referred to as the first surface 110F1.

In example embodiments, the semiconductor substrate 110 may include a P-type substrate. For example, the semiconductor substrate 110 may include any one of Si, Ge, SiGe, SiC, GaAs, InAs, and InP. For example, the semiconductor substrate 110 may be made of a P-type silicon substrate. In example embodiments, the semiconductor substrate 110 may include a P-type bulk substrate and a P-type or N-type epitaxial layer grown thereon. In other example embodiments, the semiconductor substrate 110 may include an N-type bulk substrate and a P-type or N-type epitaxial layer grown thereon. Alternatively, the semiconductor substrate 110 may include an organic plastic substrate. A well region 114 may be disposed in the interior of the semiconductor substrate 110 adjacent to the first surface 110F1 of the semiconductor substrate 110. The well region 114 may be a region doped with P-type impurities (charge carrier dopants).

In the active pixel region APR, a plurality of pixels PX may be arranged in a matrix form within the semiconductor substrate 110. Within the plurality of pixels PX, a plurality of photoelectric conversion regions PD may each be disposed. The plurality of photoelectric conversion regions PD may be regions in which light incident from the second surface 110F2 of the semiconductor substrate 110 is converted into electrical signals. The plurality of photoelectric conversion regions PD may be regions containing N-type impurities.

In the active pixel region APR, a pixel isolator 120 may be disposed within the semiconductor substrate 110, and a plurality of pixels PX may be defined by the pixel isolator 120. Within one pixel PX surrounded by the pixel isolator 120, a plurality of photoelectric conversion regions PD may be disposed. For example, as shown in FIG. 7, a pixel PX may include first through fourth sub-pixel regions SPX-1, SPX-2, SPX-3, and SPX-4, and first through fourth photoelectric conversion regions PD1, PD2, PD3, and PD4 may be disposed within the first through fourth sub-pixel regions SPX-1, SPX-2, SPX-3, and SPX-4, respectively. A floating diffusion region FD may be disposed in the central region of the pixel PX. The first through fourth sub-pixel regions SPX-1, SPX-2, SPX-3, and SPX-4 may share one floating diffusion region FD, and the four photoelectric conversion regions PD may be disposed adjacent to the floating diffusion region FD.

The pixel isolator 120 may be formed inside a pixel trench 1220T that penetrates the semiconductor substrate 110 from a first surface 110F1 to a second surface 110F2 of the semiconductor substrate 110. The pixel isolator (e.g., separator) 120 may include an insulating layer 122 conformably formed on the sidewalls of the pixel trench 120T, a conductive layer 124 filling the interior of the pixel trench 120T on the insulating layer 122, and a top insulating layer 126.

In example embodiments, the insulating layer 122 may include a metal oxide, such as hafnium oxide, aluminum oxide, tantalum oxide, or the like. In such cases, the insulating layer 122 may act as a negative fixed charge layer, but embodiments are not limited thereto. In other example embodiments, the insulating layer 122 may include an insulating material such as silicon oxide, silicon nitride, silicon oxynitride, or the like. The conductive layer 124 may include at least one of a doped polysilicon, a metal, a metal silicide, a metal nitride, or a metal-containing film.

In example embodiments, the pixel isolator 120 may include lateral extensions 120e extending in a first direction X and a second direction Y toward a center of the pixel PX. The lateral extensions 120e may be disposed between two sub-pixel regions disposed along the first direction X and between two sub-pixel regions SPX disposed along the second direction Y.

In example embodiments, the lateral extension 120e disposed in the central region of the pixel PX may not completely penetrate the semiconductor substrate 110, but may extend from the second surface 110F2 of the semiconductor substrate 110 to a level lower than the first surface 110F1 of the semiconductor substrate 110. Accordingly, the lateral extension 120e disposed in the central region of the pixel PX may vertically overlap with the second floating diffusion region FD2 disposed adjacent to the first surface 110F1 of the semiconductor substrate 110 in the central region of the pixel PX.

As exemplarily shown in FIG. 8, a device isolator 112 defining an active region AC may be formed from the first surface 110F1 of the semiconductor substrate 110. The device isolator 112 may be disposed within a device isolator trench 112T formed at a predetermined depth from the first surface 110F1 of the semiconductor substrate 110, and may include an insulating material.

Pixel transistors PXT forming a pixel circuit or a readout circuit may be disposed on the active area AC. The pixel transistors PXT may include a source follower gate SFG, a selection gate SEL, and a reset gate RG. The semiconductor substrate 110 may have a ground region GND and a floating diffusion region FD defined by the device isolator 112. The ground region GND, the floating diffusion region FD, and the active region AC may be spaced apart from each other by the device isolator 112.

In some example embodiments, the first sub-pixel SPX-1, the second sub-pixel SPX-2, the third sub-pixel SPX-3, and the fourth sub-pixel SPX-4 may be arranged in a matrix shape, as shown in FIG. 7. In some example embodiments, the first sub-pixel SPX-1 and the second sub-pixel SPX-2 may include a transfer gate TG and a source follower gate SF, the third sub-pixel SPX-3 may include a transfer gate TG and a reset gate RG, and the fourth sub-pixel SPX-4 may include a transfer gate TG and a selection gate SEL. However, the layout of the transistors shown in FIG. 7 is illustrative of some example embodiments, and embodiments are not limited to the layout of the transistors or the shape of the active region as illustrated in FIG. 7.

In example embodiments, the transfer gates TG may form the transfer transistors TX1 to TX4 (see FIG. 6), and the transfer transistors TX1 to TX4 may be configured to transfer charges generated in the photoelectric conversion regions PD1 to PD4 to the floating diffusion region FD. The reset gate RG may form the reset transistor RX (see FIG. 6), and the reset transistor RX may be configured to periodically reset the charges stored in the floating diffusion region FD. The source follower gate SFG may form the source follower transistor SF (see FIG. 6), the source follower transistor SF may act as a source follower buffer amplifier and may be configured to buffer a signal based on the charge stored in the floating diffusion region FD. The selection gate SEL may form the selection transistor SX (see FIG. 6), and the selection transistor SX may act as a switching and addressing for selecting the pixel PX.

The pixel transistor PXT may include a gate insulating layer 142 disposed on the first surface 110F1 of the semiconductor substrate 110, a pixel gate PG disposed on the gate insulating layer 142, and a source/drain region SD. The pixel gates PG may include a lower pixel gate 140 and an upper pixel gate 141. A spacer 144 may be disposed on the sidewall of the lower pixel gate 140, and a spacer may not be disposed on the sidewall of the upper pixel gate 141. A source/drain region SD may be disposed inside the semiconductor substrate 110 at the side of the lower pixel gate 140.

In example embodiments, the pixel gate PG may include at least one of doped polysilicon, metal, metal silicide, metal nitride, or metal-containing film. The gate insulating layer 142 may include a silicon oxide, or a metal oxide. The source/drain region SD may be a region doped with N-type impurities.

The transfer gate TG may have a vertically buried-gate structure, such as a dual-type buried-gate structure. As the transfer gate TG has a dual-type buried-gate structure, the effective channel area between the semiconductor substrate 110 and the transfer gate TG may be increased. In example embodiments, the transfer gate TG may include a lower transfer gate and an upper transfer gate GU as described above. The lower transfer gate may include a first buried-gate GB1, a second buried-gate GB2, and a gate connection GC, and may be arranged such that the first buried-gate GB1 and the second buried-gate GB2 are spaced apart from each other and extend in a vertical direction Z towards the interior of the semiconductor substrate 110.

As exemplarily shown in FIG. 9, a first buried-gate opening GBH1 and a second buried-gate opening GBH2 may be spaced apart from each other and extend into the semiconductor substrate 110 from the first surface 110F1 of the semiconductor substrate 110, and the bottom portions of the first buried-gate opening GBH1 and the second buried-gate opening GBH2 may be surrounded by the photoelectric conversion region PD. The gate insulating layer 142 may extend from the first surface 110F1 of the semiconductor substrate 110 onto the inner wall of the first buried-gate opening GBH1 and onto the inner wall of the second buried-gate opening GBH2. The portion of the gate insulating layer 142 disposed on the inner wall of the first buried-gate opening GBH1 and the inner wall of the second buried-gate opening GBH2 may be referred to as the buried-gate insulating layer BGI.

The first buried-gate GB1 may fill the interior of the first buried-gate opening GBH1 on the buried-gate insulating layer BGI, and the upper surface of the first buried-gate GB 1 may be disposed at a higher level than the first surface 110F1 of the semiconductor substrate 110. For example, the first buried-gate GB1 may include a first portion P1 disposed inside the first buried-gate opening GBH1, a second portion P2 connected to the first portion P1 and having an upper surface disposed in the same plane as the upper surface of the gate connection GC, and a spacer 144 may be disposed on a sidewall of the second portion P2.

The second buried-gate GB2 may fill the interior of the second buried-gate opening GBH2 on the buried-gate insulating layer BGI, and the upper surface of the second buried-gate GB 2 may be disposed at a higher level than the first surface 110F1 of the semiconductor substrate 110. For example, the second buried-gate GB2 may include a third portion P3 disposed inside the second buried-gate opening GBH2, a fourth portion P4 connected to the third portion P3 and having an upper surface disposed in the same plane as the upper surface of the gate connection GC, and a spacer 144 may be disposed on the sidewall of the fourth portion P4.

The first part P1 and the third part P3 correspond to the vertical portion of the lower transfer gate described above, and the second part P2, the gate connection GC and the fourth part P4 correspond to the horizontal portion of the lower transfer gate described above.

The gate connection GC may be integrally connected to the first buried-gate GB1 and the second buried-gate GB2 between the first buried-gate GB1 and the second buried-gate GB2. In example embodiments, the gate connection GC may be disposed between the second portion P2 of the first buried-gate GB1 and the fourth portion P4 of the second buried-gate GB2, and the upper surface of the gate connection GC may be disposed at a higher level than the upper surface of the first buried-gate GB1 and the upper surface of the second buried-gate GB2. The lower surface of the gate connection GC may be disposed at a vertical level higher than the lower surface of the first buried-gate GB1 and the lower surface of the second buried-gate GB2, and the lower surface of the gate connection GC may be in contact with the upper surface of the gate insulating layer 142.

The second portion P2 of the first buried-gate GB1 may have a first width w11 along a first horizontal direction D1, the gate connection GC may have a second width w12 along the first horizontal direction D1, and the second portion P4 of the second buried-gate GB2 may have a first width w13 along the first horizontal direction D1, wherein the first width w11, the second width w12, and the third width w13 may be the same as each other. Accordingly, the first buried-gate GB1, the gate connection GC, and the second buried-gate GB2 may have a line shape extending along, e.g., a second horizontal direction D2 in a plan view. The sidewalls of the first buried-gate GB1, the gate connection GC, and the second buried-gate GB2 may be connected to each other in coplanarity (e.g., in a straight line) in a plan view.

The gate connection GC is integrally connected to the first buried-gate GB1 and the second buried-gate GB2, and the gate connection GC may be located between the first buried-gate GB1 and the second buried-gate GB2. At a vertical level lower than the first surface 110F1 of the semiconductor substrate 110, the first buried-gate GB1 and the second buried-gate GB2 of the transfer gate TG may have two parts (e.g., the first portion P1 of the first buried-gate GB1 and the third portion P3 of the second buried-gate GB2) spaced apart from each other at a vertical level lower than the first surface 110F1 of the semiconductor substrate 110. Accordingly, the first buried-gate GB1 and the second buried-gate GB2 may serve as gate electrodes of the dual-type buried-gate structure. As the gate connection GC is integrally connected to the first buried-gate GB1 and the second buried-gate GB2 between the first buried-gate GB1 and the second buried-gate GB2, the transfer gate TG may be divided into two parts separated from each other at a vertical level lower than the first surface 110F1 of the semiconductor substrate 110 (i.e., the first portion P1 of the first buried-gate GB1 and the third portion P3 of the second buried-gate GB2), and one portion merging the first buried-gate GB1 and the second buried-gate GB2 at a vertical level higher than the first surface 110F1 of the semiconductor substrate 110 (e.g., the first buried-gate GB1 and the second buried-gate GB2 are connected to each other by the gate connection GC). For example, the transfer gate TG may be referred to as a dual-type buried-gate structure in that the transfer gate TG includes two portions separated from each other at a vertical level lower than the first surface 110F1 of the semiconductor substrate 110.

Spacers 144 may be disposed on the sidewalls of the lower transfer gates GB1, GC, GB2, and no spacers may be disposed on the sidewalls of the upper transfer gate GU. The spacers 144 may be disposed on the sidewall of the second portion P2 of the first buried-gate GB1 disposed at a level higher than the first surface 110F1 of the semiconductor substrate 110, on the sidewall of the fourth portion P4 of the second buried-gate GB2 disposed at a level higher than the first surface 110F1 of the semiconductor substrate 110, and on the sidewall of the gate connection GC. The lower surface of the spacer 144 may be in contact with the upper surface of the gate insulating layer 142, and may be disposed to surround the entirety of the sidewall portion of the transfer gate TG disposed at a level higher than the first surface 110F1 of the semiconductor substrate 110. The spacer 144 may have a first width w21 along the first horizontal direction D1, and the first width w21 may range from 20 to 50 nm, but embodiments are not limited thereto.

The floating diffusion region FD may be disposed at one side of the transfer gate TG spaced apart from the sidewalls of the transfer gate TG (e.g., the sidewalls of the first buried-gate GB1 and the sidewalls of the second buried-gate GB2) in a horizontal direction (e.g., the first horizontal direction D1 or the second horizontal direction D2 in FIG. 7).

In example embodiments, the floating diffusion region FD may include a first floating diffusion region FD1 and a second floating diffusion region FD2. The second floating diffusion region FD2 may be disposed in a central region of the pixel PX and may be shared by the first through fourth sub-pixels SPX-1 to SPX-4. The first floating diffusion region FD1 may be disposed between the second floating diffusion region FD2 and the transfer gate TG. For example, the first floating diffusion region FD1 disposed within the first fourth subpixel SPX-1 may include a first portion of a rectangular planar shape disposed adjacent to the second floating diffusion region FD2 and extending along the first horizontal direction D1, and a second portion of a trapezoidal planar shape disposed adjacent to the transfer gate TG and increasing in width as the distance from the transfer gate TG increases.

As shown in FIG. 11, the first floating diffusion area FD1 may be spaced apart from a sidewall of the first buried-gate GB1, or from a sidewall of the first buried-gate opening GBH1, by a first distance d11 along the first horizontal direction D1, and may be spaced apart from a sidewall of the second buried-gate GB2, or from a sidewall of the first buried-gate opening GBH1, by a second distance d12 along the first horizontal direction D1. For example, the second distance d12 may be the same as the first distance d11, or may have a value that approximates the first distance d11, for example, due to tolerances arising in the manufacturing process. In example embodiments, the first distance d11 and the second distance d12 may be in the range of 20 to 50 nm, but are not limited thereto.

The semiconductor substrate 110 may be disposed with an intrinsic semiconductor region IA planarly surrounding the first buried-gate GB1 and the second buried-gate GB2. The intrinsic semiconductor region IA may be disposed between the transfer gate TG and the first floating diffusion region FD1. The intrinsic semiconductor region IA may refer to a region that is not intentionally doped or injected with dopants (charge carrier dopants), and may refer to a region containing carriers (electrons and holes) that are intrinsic to the semiconductor substrate 110.

As shown in FIG. 11, the intrinsic semiconductor regions IA may include a first region IA1 surrounding the first buried-gate GB1, a second region IA2 surrounding the second buried-gate GB2, and a third region IA3 disposed between the first buried-gate GB1 and the second buried-gate GB2. For example, the first region IA1 may be positioned to vertically overlap with a portion of the spacer 144 disposed on the sidewall of the first buried-gate GB1, and the second region IA2 may be positioned to vertically overlap with a portion of the spacer 144 disposed on the sidewall of the second buried-gate GB2. The third region IA3 may be positioned to vertically overlap with the gate connection GC and a portion of the spacer 144 disposed on the sidewalls of both gate connections GC. The intrinsic semiconductor regions IA may correspond to regions that are masked by the transfer gate TG and the spacer 144 in a process for ion implantation of dopants into the first floating diffusion region FD1, such that no dopants are ion-implanted into the semiconductor substrate 110.

The intrinsic semiconductor region IA has a second width w22 along the first horizontal direction D1, wherein the second width w22 may range from 20 to 50 nm, but is not limited to. The second width w22 of the intrinsic semiconductor region IA may be the same as the first width w21 of the spacer 144, or may have a value that approximates the first width w21 for reasons such as tolerances arising from the manufacturing process.

By the sidewall of the first buried-gate GB1 and the sidewall of the second buried-gate GB2 being surrounded by the intrinsic semiconductor region IA, contact of the first floating diffusion region FD1 with the sidewall of the first buried-gate GB1 and the sidewall of the second buried-gate GB2 may be prevented or suppressed. Accordingly, the generation of trap sites caused by dopants that may occur when the first floating diffusion region FD1 is in contact with the sidewall of the first buried-gate GB1 and the sidewall of the second buried-gate GB2 may be prevented or suppressed, and the generation of noise caused by such trap sites may be prevented or suppressed.

A buried insulating layer 160 may be disposed on the first surface 110F1 of the semiconductor substrate 110. The buried insulating layer 160 may cover the ground region GND, the floating diffusion region FD, the device isolator 112, the pixel gate PG, and the transfer gate TG. In example embodiments, the buried insulating layer 160 may include silicon nitride, silicon oxynitride, or silicon oxide.

On the first surface 110F1 of the semiconductor substrate 110, contacts 162 may be disposed and penetrate the buried insulating layer 160. For example, the contacts 162 may penetrate the buried insulating layer 160 and be electrically connected to the transfer gate TG, and the pixel gate PG, and active regions such as the source/drain region SD and the second floating diffusion region FD2.

In example embodiments, one contact 162 may be disposed on the upper surface of the transfer gate TG. The contact 162 is exemplarily shown disposed in a position vertically overlapping the second buried-gate GB2, but may be disposed on the first buried-gate GB1 in other example embodiments, or on the gate connection GC in other example embodiments.

As the transfer gate TG has a dual-gate structure at a level lower than the first surface 110F1 of the semiconductor substrate 110 and a monolithic structure with the dual-gates merged into one at a level higher than the first surface 110F1 of the semiconductor substrate 110, it may not be necessary to form contacts for each of the first buried-gate GB1 and the second buried-gate GB2. For example, compared to a transfer gate having a dual-gate structure having two separate contacts, only one contact 162 is formed on the transfer gate TG according to example embodiments, which may reduce the parasitic capacitance between the contact 162 and the floating diffusion region FD, and the parasitic capacitance between the wiring layer 172 on top of the contact 162 and the floating diffusion region FD. Thus, the conversion gain of the image sensor 100 may be improved.

On top of the buried insulating layer 160, an upper wiring structure 170 may be disposed. The upper wiring structure 170 may be formed as a laminated structure of a plurality of layers. The upper wiring structure 170 may include a wiring layer 172 and an insulating layer 174 surrounding the wiring layer 172. Wiring layer 172 may include at least one of polysilicon doped or undoped with impurities, metal, metal silicide, metal nitride, or metal-containing film. For example, the wiring layer 172 may include tungsten, aluminum, copper, tungsten silicide, titanium silicide, tungsten nitride, titanium nitride, doped polysilicon, and the like. The insulating layer 174 may include an insulating material such as silicon oxide, silicon nitride, silicon oxynitride, or the like.

A back insulating layer 182 may be disposed on the second surface 110F2 of the semiconductor substrate 110. The back insulating layer 182 may be disposed over substantially the entire area of the second surface 110F2 of the semiconductor substrate 110, and the back insulating layer 182 may contact the surface of the pixel isolator 120 disposed at the same level as the second surface 110F2 of the semiconductor substrate 110. In example embodiments, the back insulating layer 182 may include a metal oxide, such as hafnium oxide, aluminum oxide, tantalum oxide, or the like. In other example embodiments, the back insulating layer 182 may include an insulating material such as a silicon oxide, silicon nitride, silicon oxynitride, low dielectric constant material, or the like.

A passivation layer 184 may be disposed on the back insulating layer 182, and a color filter 186 and a microlens 188 may be disposed on the passivation layer 184. Optionally, a support substrate may be further disposed on the first surface 110F1 of the semiconductor substrate 110.

In general, as the size of the pixel PX decreases, the size of the mask in the ion implantation process for forming the floating diffusion region FD also decreases, and therefore, defects may occur in the mask patterning process. If the transfer gate is formed first and the floating diffusion region FD is formed afterwards, there is a problem that the floating diffusion region FD is formed to contact the inner wall of the transfer gate trench, thereby causing trap sites by dopants, which causes noise.

However, according to example embodiments, the floating diffusion region FD may be formed at a position spaced apart from the sidewalls of the first and second buried-gates GB1 and GB2 by using the spacer 144 disposed on the sidewall of the transfer gate TG as a magnetic alignment mask. Accordingly, noise generation caused by dopants that may occur when the floating diffusion region FD is formed adjacent to the sidewalls of the buried-gates GB1 and GB2 may be reduced, and the two buried-gates GB1 and GB2 may be electrically isolated from each other, the number of contacts 162 and the length of the wiring layer 172 may be reduced, and thus the parasitic capacitance may be reduced, thereby increasing the conversion gain of the image sensor 100.

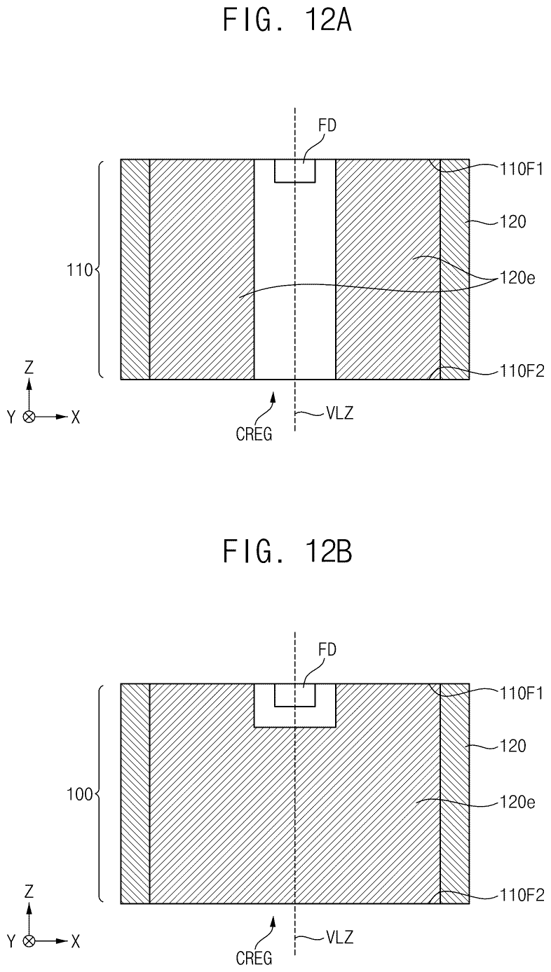

FIGS. 12A and 12B are diagrams (e.g., plan view) illustrating example embodiments of a pixel isolator included in an image sensor according to example embodiments. Hereinafter, descriptions that are redundant with the foregoing descriptions may be omitted.

In an example embodiment, as shown in FIG. 12A, a lateral extension 120e of the pixel isolator 120 may have a portion corresponding to a central region CREG on a central vertical line VLZ removed in the vertical direction Z from the first surface 110F1 of the semiconductor substrate 110 to the second surface 110F2 of the semiconductor substrate 110.

In another example embodiment, as shown in FIG. 12B, the lateral extension 120e of the pixel isolator 120 may have a portion corresponding to the central region CREG on the central vertical line VLZ removed only partially from the first surface 110F1 of the semiconductor substrate 110.

A floating diffusion region FD may be disposed in the central region CREG from which the lateral extension 120e of the pixel isolator 120 has been removed. The central region CREG allows electrons to pass between the sub-pixels, which may be controlled by the potential profile formed on the semiconductor substrate 110 depending on the length of the removal and the manufacturing process.

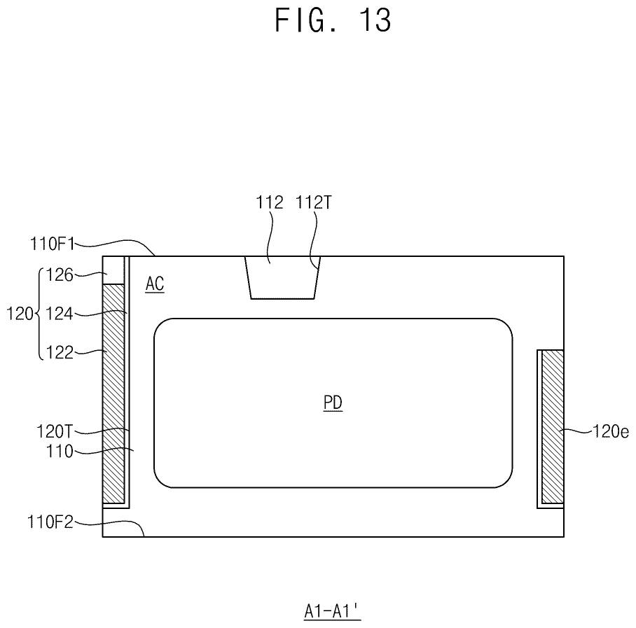

FIGS. 13 through 17, 18A, 18B, 19 and 20 are diagrams illustrating a method of manufacturing an image sensor according to example embodiments. Hereinafter, descriptions that are redundant with the foregoing descriptions may be omitted.

Referring to FIG. 13, a semiconductor substrate 110 is provided. A photoelectric conversion region PD may be formed in the semiconductor substrate 110 by an ion implantation process.

A pixel isolator 120 may then be formed extending from the first surface 110F1 of the semiconductor substrate 110 into the interior of the semiconductor substrate 110. The pixel isolator 120 may include a lateral extension 120e, and the lateral extension 120e may not be formed from the central region of the pixel PX to a predetermined height from the first surface 110F1 of the semiconductor substrate 110.

Then, a portion may be removed from the first surface 110F1 of the semiconductor substrate 110 to form a device isolator trench 112T, and an insulating material may be filled in the device isolator trench 112T to form the device isolator 112. The device isolator 112 may define an active region AC, a ground region GND, and a preliminary floating diffusion region FDP.

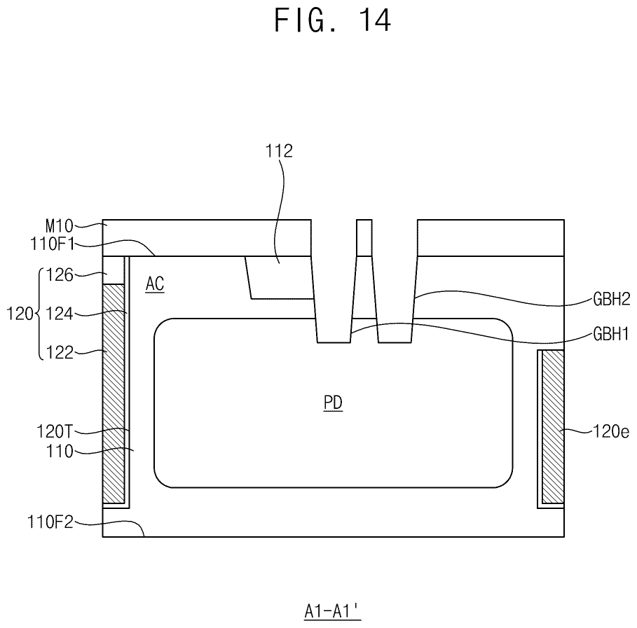

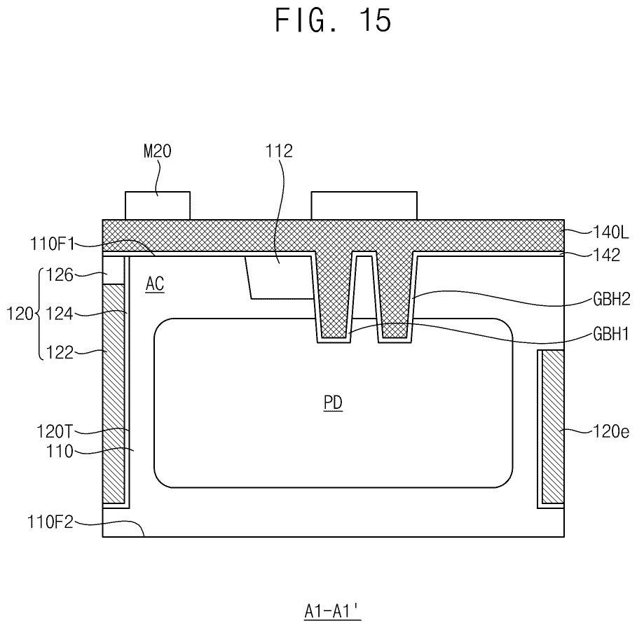

Referring to FIG. 14, a first mask M10 may be formed on the first surface 110F1 of the semiconductor substrate 110, and the first mask M10 may be used as an etch mask to form a first buried-gate opening GBH1 and a second buried-gate opening GBH2 extending from the first surface 110F1 of the semiconductor substrate 110 into the interior of the semiconductor substrate 110.

The first buried-gate opening GBH1 and the second buried-gate opening GBH2 may be disposed adjacent to the preliminary floating diffusion region FDP, and the bottom portions of the first buried-gate opening GBH1 and the second buried-gate opening GBH2 may be surrounded by the photoelectric conversion region PD. Thereafter, the first mask M10 may be removed.

Referring to FIG. 15, a gate insulating layer 142 may then be formed on the first surface 110F1 of the semiconductor substrate 110, and on the inner walls of the first buried-gate opening GBH1 and the second buried-gate opening GBH2.

A first deposition process may then be performed on the gate insulating layer 142 to form a gate layer 140L (the first poly layer PC1 described above) that fills the first buried-gate opening GBH1 and the second buried-gate opening GBH2. The gate layer 140L may be formed with a suitable thickness to sufficiently fill the first buried-gate opening GBH1 and the second buried-gate opening GBH2. A second mask M20 may then be formed on the gate layer 140L.

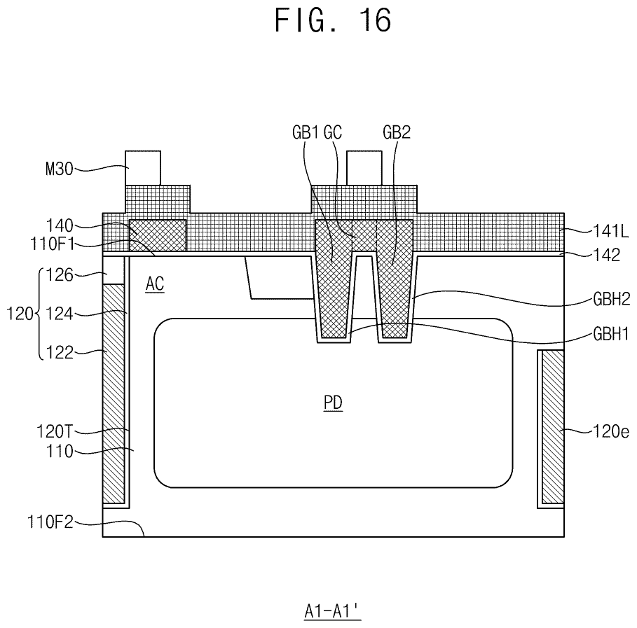

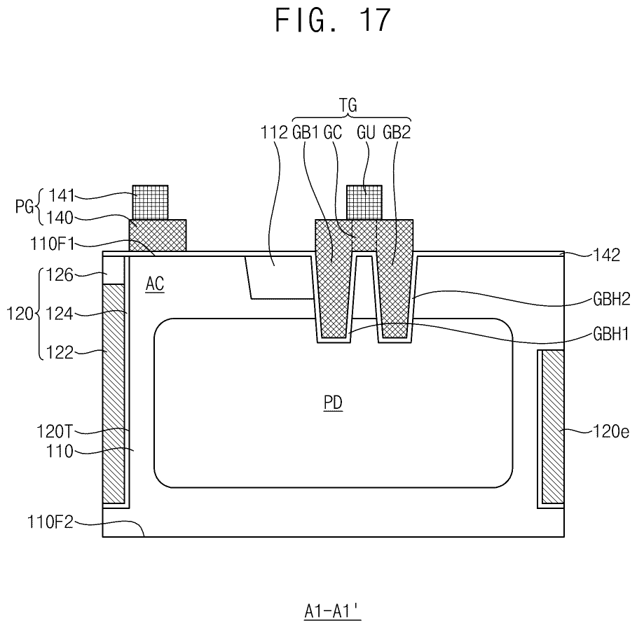

Referring to FIG. 16, the second mask M20 may be used as an etch mask to pattern the gate layer 140L to form the lower pixel gate 140 and the lower transfer gates GB1, GC, GB2.

In example embodiments, the lower transfer gates may include a first buried-gate GB1 disposed inside the first buried-gate opening GBH1, a second buried-gate GB2 disposed inside the second buried-gate opening GBH2, and a first gate connection GC disposed between the first buried-gate GB1 and the second buried-gate GB2 on the first surface 110F1 of the semiconductor substrate 110. The first buried-gate GB1 and the second buried-gate GB2 may be spaced apart from each other and arranged to extend in the vertical direction Z towards the interior of the semiconductor substrate 110.

Subsequently, a second deposition process may be performed to form the gate layer 141L (the second poly layer PC2 described above). A third mask M30 may then be formed on the gate layer 141L, and the gate layer 141L may be patterned using the third mask M30 as an etch mask to form the upper pixel gate 141 and the upper transfer gate GU as shown in FIG. 17.

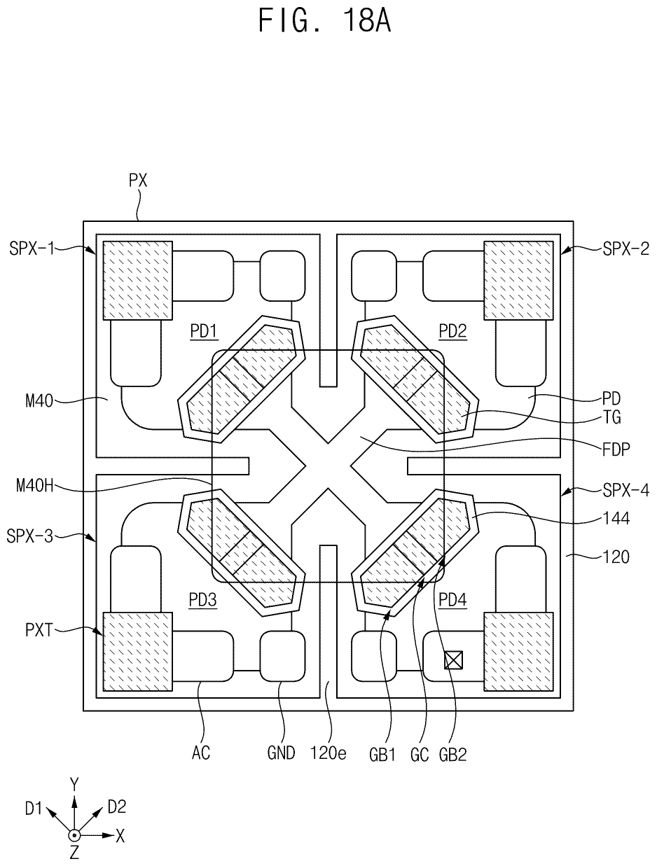

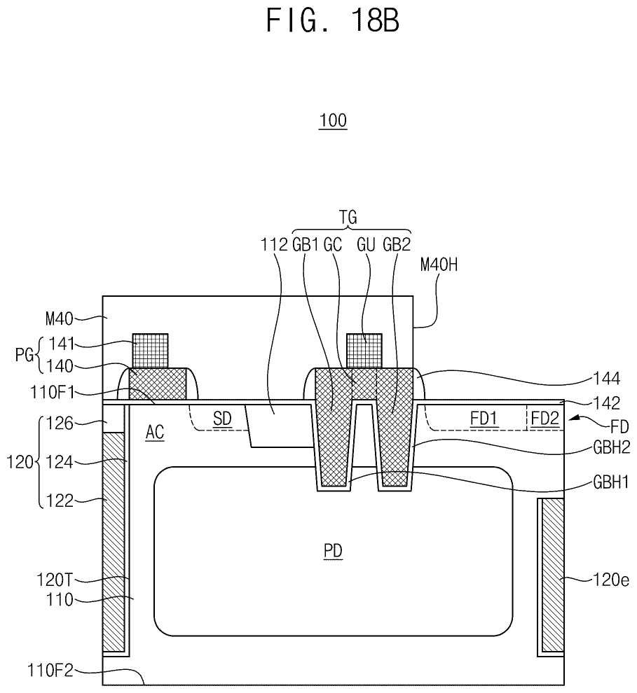

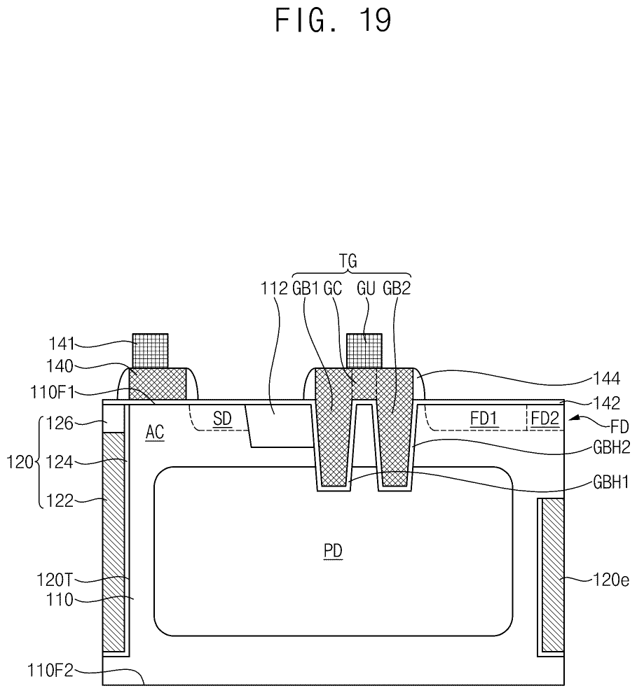

Referring to FIGS. 18A and 18B, an ion implantation mask M40 covering the pixel gate PG and the transfer gate TG may be formed on the first surface 110F1 of the semiconductor substrate 110. The ion implantation mask M40 may have an opening M40H exposing a central region of the pixel PX. The opening M40H may be arranged to vertically overlap with a plurality of transfer gates TG and the spacers 144, and the preliminary floating diffusion region FDP.

As the ion implantation mask M40 has a relatively large opening M30H, poor patterning in the ion implantation mask M40 formation process may be avoided.

Referring to FIG. 19, the first and second floating diffusion regions FD1 and FD2 may be formed by injecting a dopant into the region exposed in the opening M40H of the ion implantation mask M40. The first and second floating diffusion regions FD1 and FD2 may have different dopant levels, and the ion implantation process to form the first and second floating diffusion regions FD1 and FD2 may be performed sequentially.

According to example embodiments, no dopant may be implanted inside the semiconductor substrate 110 covered by the plurality of transfer gates TG and the spacers 144, thereby forming the intrinsic semiconductor region IA around the plurality of transfer gates TG.

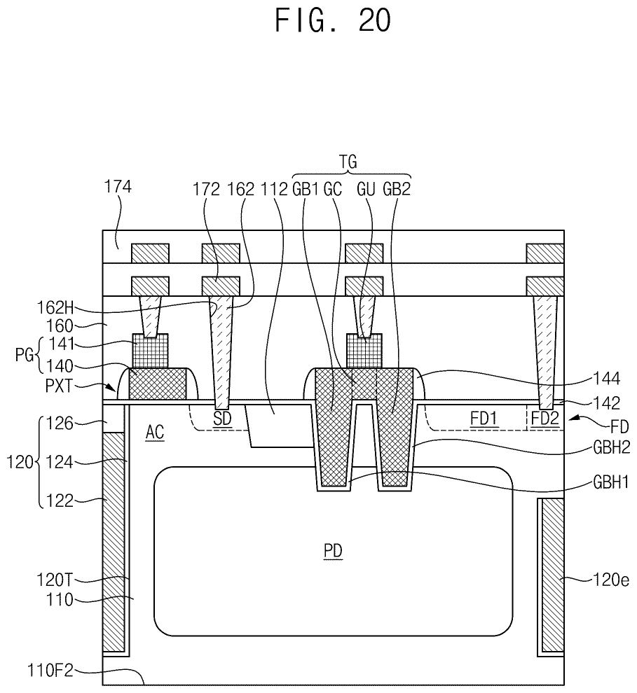

Referring to FIG. 20, the ion implantation mask M40 may be removed. After that, a buried insulation layer 160 covering the pixel gate PG and the transfer gates TG may be formed on the gate insulating layer 142. Contacts 162 may then be formed through the buried insulating layer 160 to electrically connect to the active region, the transfer gate TG, and the pixel gate PG.

Referring again to FIG. 8, a portion of some thickness may be removed from the second surface 110F2 of the semiconductor substrate 110, a back insulating layer 182 and a passivation layer 184 may be formed on the second surface 110F2 of the semiconductor substrate 110, and a color filter 186 and a microlens 188 may be formed on the passivation layer 184.

FIG. 21 is a diagram illustrating a perspective view of an image sensor according to example embodiments.

Referring to FIG. 21, an image sensor 100 may be a stacked image sensor including a first chip C1 and a second chip C2 stacked in a vertical direction. The first chip C1 may include an active pixel region APR and a first pad region PDR1, and the second chip C2 may include a peripheral circuit region PCR and a second pad region PDR2.

A plurality of first pads PAD1 of the first pad region PDR1 may be configured to transmit and receive electrical signals to and from an external device or the like. The peripheral circuit region PCR may include a logic circuit block LC, which may include a plurality of CMOS transistors. The peripheral circuitry region PCR may provide a signal to each active pixel PX of the active pixel region APR or may control an output signal from each active pixel PX. The first pad PAD1 in the first pad region PDR1 may be electrically connected, through a via structure VS, to the second pad PAD2 in the second pad region PDR2.

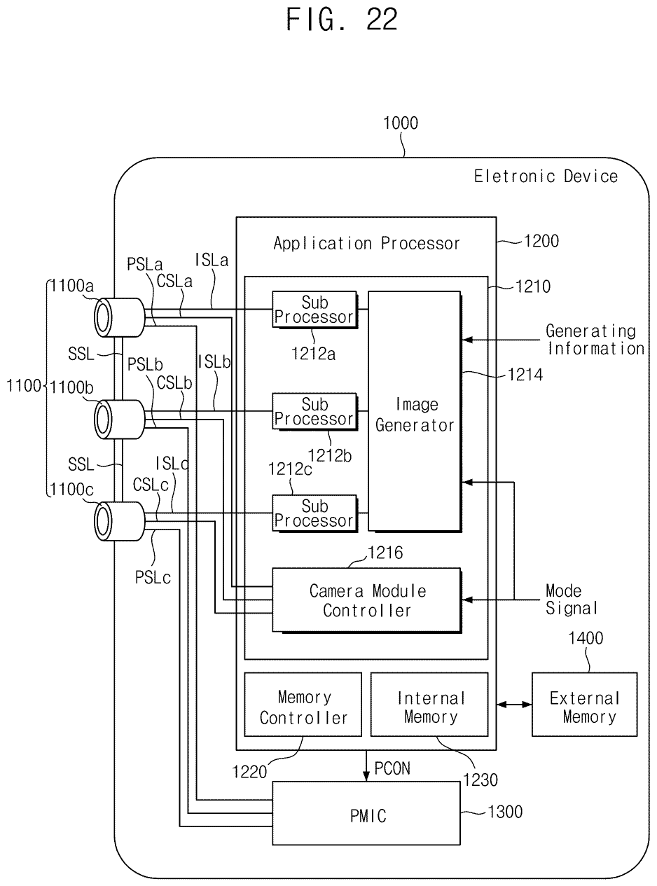

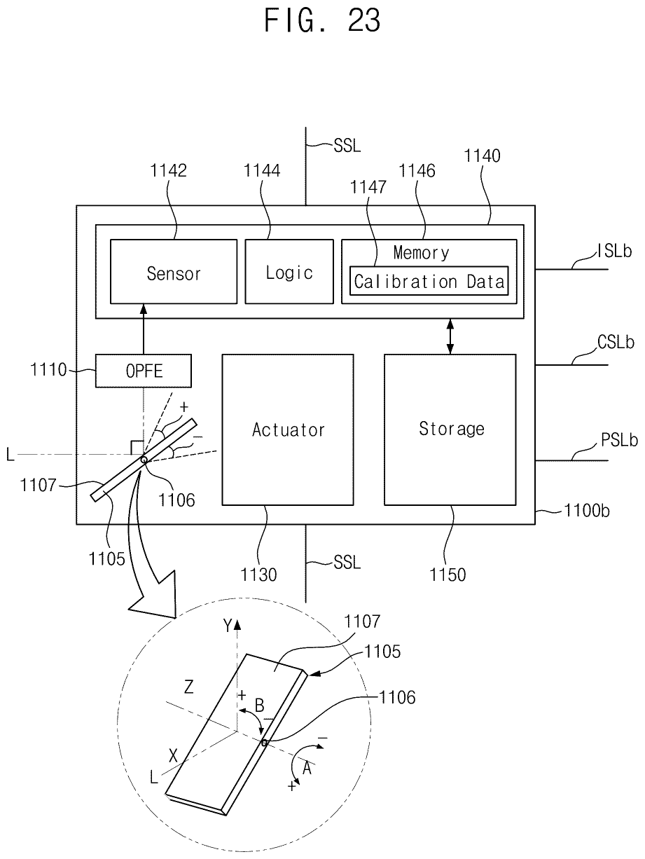

FIG. 22 is a block diagram illustrating an electronic device according to example embodiments, and FIG. 23 is a block diagram illustrating a camera module included in the electronic device of FIG. 22.

Referring to FIG. 22, an electronic device 1000 may include a camera module group 1100, application processor 1200, a power management integrated circuit (PMIC) 1300 and/or an external memory 1400.

The camera module group 1100 may include a plurality of camera modules 1100a, 1100b, and 1100c. FIG. 22 illustrates the three camera modules 1100a, 1100b, and 1100c as an example, but embodiments are not limited to a particular number of camera modules. According to example embodiments, the camera module group 1100 may include two camera modules, and four or more camera modules.

Hereinafter, an example configuration of the camera module 1100b is described with reference to FIG. 23. According to example embodiments, the same descriptions may be applied to the other camera modules 1100a and 1100c.

Referring to FIG. 23, the camera module 1100b may include a prism 1105, an optical path folding element (OPFE) 1110, an actuator 1130, an image sensing device 1140 and a storage device 1150.

The prism 1105 may include a reflection surface 1107 to change a path of a light L incident on the prism 1105.

In some example embodiments, the prism 1105 may be configured to change the path of the light L incident in a first direction X to the path in a second direction Y perpendicular to the first direction X. In addition, the prism 1105 may rotate the reflection surface 1107 around a center axis 1106 and/or rotate the center axis 1106 in the B direction to align the path of the reflected light along the second direction Y. In addition, the OPFE 1110 may move in a third direction perpendicular to the first direction X and the second direction Y.

In some example embodiments, a rotation angle of the prism 1105 may be smaller than 15 degrees in the positive (+) A direction and greater than 15 degrees in the negative (−) A direction, but embodiments are not limited thereto.

In some example embodiments, the prism 1105 may rotate within 20 degrees in the positive B direction and the negative B direction.

In some example embodiments, the prism 1105 may move the reflection surface 1107 in the third direction Z that is in parallel with the center axis 1106.

The OPFE 1110 may include optical lenses that are divided into m groups where m is a positive integer. The m lens group may move in the second direction Y to change an optical zoom ratio of the camera module 1100b. For example, the optical zoom ratio may be changed in a range of 3K, 5K, and so on by moving the m lens group, when K is a basic optical zoom ratio of the camera module 1100b.

The actuator 1130 may be configured to move the OPFE 1110 or the optical lens to a specific position. For example, the actuator 1130 may adjust the position of the optical lens for accurate sensing such that an image sensor 1142 may be located at a position corresponding to a focal length of the optical lens.

The image sensing device 1140 may include the image sensor 1142, a control logic 1144, and/or a memory 1146. The image sensor 1142 may be configured to capture and/or sense an image using the light provided through the optical lens. The control logic 1144 may control overall operations of the camera module 1100b. For example, the control logic 1144 may provide control signals through control signal line CSLb to control the operation of the camera module 1100b. The image sensor 1142 may include, for example, an image sensor (e.g., the image sensor 600) and/or a pixel (e.g., the pixel PX) according to at least one of the above described example embodiments.

The memory 1146 may store information such as calibration data 1147 for the operation of the camera module 1100b. For example, the calibration data 1147 may include information for generation of image data based on the provided light, such as information on the above-described rotation angle, a focal length, information on an optical axis, and so on. When the camera module 1100b is implemented as a multi-state camera having a variable focal length depending on the position of the optical lens, the calibration data 1147 may include multiple focal length values and auto-focusing values corresponding to the multiple states.

The storage device 1150 may store the image data sensed using the image sensor 1142. The storage device 1150 may be disposed outside of (external to) the image sensing device 1140, and the storage device 1150 may be stacked with a sensor chip including the image sensing device 1140. The storage device 1150 may be implemented with an electrically erasable programmable read-only memory (EEPROM), but embodiments are not limited thereto.

Referring to FIGS. 22 and 23, each of the camera modules 1100a, 1100b, and 1100c may include the actuator 1130. In some example embodiments, the camera modules 1100a, 1100b, and 1100c may include the same or different calibration data 1147 depending on the operations of the actuators 1130.

In some example embodiments, one camera module 1100b may have a folded lens structure included the above-described prism 1105 and the OPFE 1110, and the other camera modules 1100a and 1100b may have a vertical structure without the prism 1105 and the OPFE 1110.

In some example embodiments, one camera module 1100c may be a depth camera configured to measure distance information of an object using an infrared light. In some example embodiments, the application processor 1200 may merge the distance information provided from the camera module (e.g., depth camera) 1100c and image data provided from the other camera modules 1100a and 1100b to generate a three-dimensional depth image.

In some example embodiments, at least two camera modules among the camera modules 1100a, 1100b, and 1100c may have different field of views, for example, through different optical lenses.

In some example embodiments, each of the camera modules 1100a, 1100b, and 1100c may be separated physically from each other. For example, the camera modules 1100a, 1100b, and 1100c may each include a dedicated image sensor 1142.

The application processor 1200 may include an image processing device 1210, a memory controller 1220 and an internal memory 1230. The application processor 1200 may be separated from the camera modules 1100a, 1100b, and 1100c. For example, the application processor 1200 may be implemented as one chip and the camera modules 1100a, 1100b, and 1100c may be implemented as another chip or other chips.

The image processing device 1210 may include a plurality of sub-processors 1212a, 1212b, and 1212c, an image generator 1214 and a camera module controller 1216.

The image data generated by the camera modules 1100a, 1100b, and 1100c may be provided to the sub-processors 1212a, 1212b, and 1212c through distinct image signal lines ISLa, ISLb, and ISLc, respectively. For example, the transfer of the image data may be performed using a camera serial interface (CSI) based on the mobile industry processor interface (MIPI), but embodiments are not limited thereto.

In some example embodiments, one sub-processor may be assigned commonly to two or more camera modules. In some example embodiments, a multiplexer may be used to transfer the image data selectively from one of the camera modules to the shared sub-processor.

The image data from the sub-processors 1212a, 1212b, and 1212c may be provided to the image generator 1214. The image generator 1214 may generate an output image using the image data from the sub-processors 1212a, 1212b, and 1212c according to image generating information or a mode signal. For example, the image generator 1213 may merge at least a portion of the image data from the camera modules 1100a, 1100b, and 1100c having the different fields of view to generate the output image according to the image generating information or the mode signal. In addition, the image generator 1214 may select, as the output image, one of the image data from the camera modules 1100a, 1100b, and 1100c according to the image generating information or the mode signal.

In some example embodiments, the image generating information may include a zoom factor or a zoom signal. In some example embodiments, the mode signal may be a signal based on a selection of a user.

When the image generating information is the zoom factor and the camera modules 1100a, 1100b, and 1100c have different fields of views, the image generator 1214 may perform different operations depending on the zoom signal. For example, when the zoom signal is a first signal, the image generator 1214 may merge the image data from the different camera modules to generate the output image. When the zoom signal is a second signal different from the first signal, the image generator 1214 may select, as the output image, one of image data from the camera modules 1100a, 1100b, and 1100c.

In some example embodiments, the image generator 1214 may receive the image data of different exposure times from the camera modules 1100a, 1100b, and 1100c. In some example embodiments, the image generator 1214 may perform high dynamic range (HDR) processing with respect to the image data from the camera modules 1100a, 1100b, and 1100c to generate the output image having the increased dynamic range.

The camera module controller 1216 may provide control signals to the camera modules 1100a, 1100b, and 1100c. The control signals generated by the camera module controller 1216 may be provided to the camera modules 1100a, 1100b, and 1100c through the distinct control signal lines CSLa, CSLb, and CSLc, respectively.

In some example embodiments, one of the camera modules 1100a, 1100b, and 1100c may be designated as a master camera according to the image generating information of the mode signal, and the other camera modules may be designated as slave cameras.

The camera module acting as the master camera may be changed according to the zoom factor or an operation mode signal. For example, when the camera module 1100a has a wider field of view than the camera module 1100b and the zoom factor indicates a lower zoom magnification, the camera module 1100b may be designated as the master camera. In contrast, when the zoom factor indicates a higher zoom magnification, the camera module 1100a may be designated as the master camera.

In some example embodiments, the control signals provided from the camera module controller 1216 may include a synch enable signal. For example, when the camera module 1100b is the master camera and the camera modules 1100a and 1100c are the slave cameras, the camera module controller 1216 may provide the synch enable signal to the camera module 1100b. The camera module 1100b may generate a synch signal based on the provided synch enable signal and provide the synch signal to the camera modules 1100a and 1100c through a synch signal line SSL. As such, the camera modules 1100a, 1100b and 1100c may transfer the synchronized image data to the application processor 1200 based on the synch signal.

In some example embodiments, the control signals provided from the camera module controller 1216 may include information on the operation mode. The camera modules 1100a, 1100b, and 1100c may operate in a first operation mode or a second operation mode based on the information from the camera module controller 1216.

In the first operation mode, the camera modules 1100a, 1100b, and 1100c may generate image signals with a first speed (e.g., a first frame rate) and encode the image signals with a second speed higher than the first speed (e.g., a second frame rate higher than the first frame rate) to transfer the encoded image signals to the application processor 1200. The second speed may be lower than thirty times the first speed. The application processor 1200 may store the encoded image signals in the internal memory 1230 or the external memory 1400. The application processor 1200 may read out and decode the encoded image signals to provide display data to a display device. For example, the sub-processors 1212a, 1212b, and 1212c may perform the decoding operation and the image generator 1214 may process the decoded image signals.

In the second operation mode, the camera modules 1100a, 1100b, and 1100c may generate image signals with a third speed lower than the first speed (e.g., the third frame rate lower than the first frame rate) to transfer the generated image signals to the application processor 1200. For example, the image signals that are not encoded may be provided to the application processor 1200. The application processor 1200 may process the received image signals or store the receive image signals in the internal memory 1230 or the external memory 1400.

The PMIC 1300 may be configured to provide a power supply voltage to the camera modules 1100a, 1100b, and 1100c, respectively. For example, the PMIC 1300 may provide, under control of the application processor 1200, a first power to the camera module 1100a through a power line PSLa, a second power to the camera module 1100b through a power line PSLb, and a third power to the camera module 1100c through a power line PSLc.

The PMIC 1300 may generate the powers respectively corresponding to the camera modules 1100a, 1100b, and 1100c and control power levels, in response to a power control signal PCON from the application processor 1200. The power control signal PCON may include information on the power depending on the operation modes of the camera modules 1100a, 1100b, and 1100c. For example, the operation modes may include a low power mode in which the camera modules 1100a, 1100b, and 1100c operate in low power. The power levels of the camera modules 1100a, 1100b, and 1100c may be the same as or different from each other. In addition, the power levels may be changed dynamically or adaptively.

As described above, the pixel of the image sensor according to example embodiments may reduce coupling capacitance between gates and other components and improve electrical characteristics of the pixel and image sensor, by adopting the dual-gate structure including the lower gate and the upper gate having the smaller horizontal size than the lower gate. Furthermore, the pixels of the image sensor according to example embodiments may efficiently improve the electrical characteristics of the pixel and image sensor without excessive changes to the existing layout design by changing only the size and position of the upper gate while keeping the layout of the lower gate unchanged.

The example embodiments may be applied to any electronic devices and systems including an image sensor. For example, the example embodiments may be applied to systems such as a mobile phone, a smart phone, a personal digital assistant (PDA), a portable multimedia player (PMP), a digital camera, a camcorder, a personal computer (PC), a server computer, a workstation, a laptop computer, a digital TV, a set-top box, a portable game console, a navigation system, a wearable device, an internet of things (IoT) device, an internet of everything (IoE) device, an e-book, a virtual reality (VR) device, an augmented reality (AR) device, an augmented reality (AR) device, a vehicle navigation device, a video phone, a monitoring system, an auto focusing system, a tracking system, a motion detection system, etc.

The foregoing is illustrative of example embodiments and is not to be construed as limiting the invention. Although a few example embodiments have been described, those skilled in the art will readily appreciate that many modifications are possible in the example embodiments without materially departing from the example embodiments.

What is claimed is:

1. A pixel of an image sensor, comprising:
a photodiode disposed in a lower portion of a semiconductor substrate;
a floating diffusion region disposed in an upper portion of the semiconductor substrate;
a first gate including a first lower gate disposed on the semiconductor substrate and a first upper gate disposed on the first lower gate; and
a second transistor including a first source/drain region, a second source/drain region and a second gate,
wherein the first gate is a transfer gate, and the transfer gate is a part of a first transistor,
wherein the first source/drain region and the second source/drain region are disposed in the upper portion of the semiconductor substrate,
wherein the second gate is disposed on the semiconductor substrate between the first source/drain region and the second source/drain region, and
wherein the second gate includes a second lower gate and a second upper gate disposed on the second lower gate.

2. The pixel of claim 1, wherein:
a size in a horizontal direction of the first upper gate is smaller than a size in the horizontal direction of the first lower gate,
the horizontal direction being parallel to an upper surface of the semiconductor substrate, and
a size in the horizontal direction of the second upper gate is smaller than a size in the horizontal direction of the first lower gate.

3. The pixel of claim 1, wherein:
a thickness in a vertical direction of the first upper gate is larger than a thickness in the vertical direction of the first lower gate,
the vertical direction being perpendicular to an upper surface of the semiconductor substrate, and
a thickness in the vertical direction of the second upper gate is larger than a thickness in the vertical direction of the second lower gate.

4. The pixel of claim 1, wherein:
the first lower gate and the second lower gate are formed simultaneously by patterning a first poly layer that is formed by a first deposition process, and
the first upper gate and the second upper gate are formed simultaneously by patterning a second poly layer formed by a second deposition process that is performed after the first deposition process.

5. The pixel of claim 1,
wherein a doping concentration of the first lower gate is the same as that of the second lower gate, and
wherein a doping concentration of the first upper gate is the same as that of the second upper gate.

6. The pixel of claim 1, further comprising:
vertical contacts disposed on the first upper gate and the second upper gate.

7. The pixel of claim 1, wherein:
the first lower gate has a first end and a second end,
the first end and the second end are disposed opposite to each other in a horizontal direction, and the first end is farther from the floating diffusion region than the second end, and
the first upper gate is disposed on the first lower gate at the first end of the first lower gate.

8. The pixel of claim 1, wherein:
the second lower gate has a first end and a second end,
the first end and the second end are disposed opposite to each other in a horizontal direction in a plan view,
the first end is farther than the second end from a pixel isolator electrically isolating the pixel from neighboring pixels, and
the second upper gate is disposed on the second lower gate adjacent to the first end.

9. The pixel of claim 1, wherein the first lower gate has a buried-gate structure including a horizontal portion extending horizontally on an upper surface of the semiconductor substrate and a vertical portion extending vertically into an interior of the semiconductor substrate.

10. The pixel of claim 9,
wherein the horizontal portion and the vertical portion of the first lower gate are formed as a continuous homogenous pattern, and
wherein the first upper gate is formed as a second pattern.

11. The pixel of claim 9, wherein the first lower gate has a dual-type buried-gate structure including the vertical portion of the first lower gate having two buried-gates that are spaced apart from each other in a horizontal direction.

12. The pixel of claim 1, further comprising:
spacers disposed on corresponding sidewalls of the first lower gate and the second lower gate,
wherein no spacers are disposed on sidewalls of the first lower gate and the second lower gate.

13. A method of manufacturing an image sensor including a pixel, comprising:
forming a gate insulating layer on a semiconductor substrate;
forming a first poly layer on the gate insulating layer by performing a first deposition process;
forming a first lower gate and a second lower gate simultaneously by patterning the first poly layer;
forming a second poly layer on the first lower gate and the second lower gate by performing a second deposition process; and
forming a first upper gate and a second upper gate on the first lower gate and the second lower gate simultaneously by patterning the second poly layer,
wherein the first lower gate and the first upper gate constitute a transfer gate and the transfer gate is a part of a transfer transistor.

14. The method of claim 13, wherein:
a size in a horizontal direction of the first upper gate is smaller than a size in the horizontal direction of the first lower gate,
the horizontal direction being parallel to an upper surface of the semiconductor substrate, and
a size in the horizontal direction of the second upper gate is smaller than a size in the horizontal direction of the first lower gate.

15. The method of claim 13, wherein a thickness of the second poly layer is larger than a thickness of the first poly layer.

16. The method of claim 13, further comprising:
doping the first lower gate and the second lower gate simultaneously by performing a first ion implantation process before forming the second poly layer; and
doping the first upper gate and the second upper gate simultaneously by performing a second ion implantation process after forming the first upper gate and the second upper gate.

17. The method of claim 13, further comprising:
doping the first lower gate, the first upper gate, the second lower gate and the second upper gate simultaneously by performing an ion implantation process after forming the first upper gate and the second upper gate.

18. An image sensor comprising:
a pixel array including a plurality of pixels configured to perform a sensing operation by collecting photo-charges generated by incident light;
a row driver configured to drive the pixel array row by row; and
a controller configured to control the pixel array and the row driver,
wherein a pixel of the plurality of pixels includes:
a photodiode disposed in a lower portion of a semiconductor substrate,
a floating diffusion region disposed in an upper portion of the semiconductor substrate,
a first gate including a first lower gate disposed on the semiconductor substrate and a first upper gate disposed on the first lower gate, and
a second transistor including a first source/drain region, a second source/drain region and a second gate,
wherein the first gate is a transfer gate,
wherein the transfer gate is a part of a first transistor,
wherein the first source/drain region and the second source/drain region are disposed in the upper portion of the semiconductor substrate,
wherein the second gate is disposed on the semiconductor substrate between the first source/drain region and the second source/drain region, and
wherein the second gate includes a second lower gate and a second upper gate disposed on the second lower gate.

19. The image sensor of claim 18, wherein:
a size in a horizontal direction of the first upper gate is smaller than a size in the horizontal direction of the first lower gate,
the horizontal direction is parallel to an upper surface of the semiconductor substrate, and
a size in the horizontal direction of the second upper gate is smaller than a size in the horizontal direction of the first lower gate.

20. The image sensor of claim 18, wherein:
a thickness in a vertical direction of the first upper gate is larger than a thickness in the vertical direction of the first lower gate,
the vertical direction is perpendicular to an upper surface of the semiconductor substrate, and
a thickness in the vertical direction of the second upper gate is larger than a thickness in the vertical direction of the second lower gate.
